(19) United States
(12) Patent Application Publication
(10) Pub. No.: US 2019/0006215 A1
(43) Pub. Date: Jan. 3, 2019

(54) LIGHT IRRADIATION TYPE HEAT TREATMENT APPARATUS, AND HEAT TREATMENT METHOD

(71) Applicant: SCREEN Holdings Co., Ltd., Kyoto (JP)

(72) Inventors: Takayuki AOYAMA, Kyoto-shi (JP); Shinichi IKEDA, Kyoto-shi (JP); Akitsugu UEDA, Kyoto-shi (JP)

(21) Appl. No.: 16/017,177

(22) Filed: Jun. 25, 2018

(30) Foreign Application Priority Data
Jun. 28, 2017 (JP) 2017-125974

(51) Int. Cl. H01L 21/67; H01L 21/677; H01L 21/687; H01L 21/268; H01L 21/324; H05B 3/00

(52) U.S. Cl. CPC H01L 21/67276; H01L 21/67115; H01L 21/67742; G01N 2021/1725; H01L 21/2686; H01L 21/324; H05B 3/0047; H01L 21/68707

(57) ABSTRACT

A semiconductor wafer transport mode of a heat treatment apparatus is switchable between two modes of a “high throughput mode” and a “low oxygen concentration mode” as appropriate. In the “low oxygen concentration mode”, a first cooling chamber is used only as a path for transferring the semiconductor wafer, and a second cooling chamber is used only as a dedicated cooling unit for cooling the semiconductor wafer subjected to flash heating. On the other hand, in the “high throughput mode”, both of the first cooling chamber and the second cooling chamber are used as paths for transferring the semiconductor wafer, and as the cooling units, too.

### BACKGROUND OF THE INVENTION

### Field of the invention

The present invention relates to a heat treatment apparatus and a heat treatment method that irradiate a thin plate-like precision electronic substrate (hereinafter referred to simply as a “substrate”) such as a semiconductor wafer with flashes of light to heat the substrate.

### Description of the Background Art

In a semiconductor device manufacturing process, attention has been given to flash lamp annealing (FLA) for heating a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

This flash lamp annealing is used for a heating treatment that needs to be performed in an extremely short time such as typically activation of impurities implanted in a semiconductor wafer. By irradiating a surface of a semiconductor wafer implanted with impurities by an ion implantation process, with a flash of light from flash lamps, it is possible to raise a temperature of the surface of the semiconductor wafer up to an activation temperature only for an extremely short time, and only activate impurities without deeply diffusing the impurities.

A heat treatment apparatus for performing flash lamp annealing employing, for example, a configuration disclosed in US2014/0235072 is used. A flash lamp annealer disclosed in US2014/0235072 is provided with a treatment chamber for performing an annealing process, and a cooling chamber for performing a cooling treatment on a semiconductor wafer. Typically, during flash lamp annealing, the semiconductor wafer preheated to several 100° C. is irradiated with a flash of light to instantaneously raise the wafer surface to 1000° C. or more. The semiconductor wafer heated to such a high temperature cannot be transported out of the flash lamp annealer. Therefore, the semiconductor wafer subjected to the heating treatment is transported into the cooling chamber and is subjected to the cooling treatment.

However, even the instantaneous flash irradiation heats the surface of the semiconductor wafer to a high temperature equal to or more than 1000° C. Therefore, cooling the semiconductor wafer having such a high temperature requires a very long time. Therefore, even when the flash heating is finished in a short time, the subsequent cooling treatment requires a long time. Therefore, there is a problem that a cooling time becomes a bottleneck factor and causes a decrease in a throughput of the entire apparatus. When the cooling time requires a long time, immediately after the cooled semiconductor wafer is transported out of the cooling chamber and an oxygen concentration in the chamber rapidly rises, a next semiconductor wafer subjected to a heating treatment is transported into the cooling chamber. Therefore, it is difficult to sufficiently decrease the oxygen concentration in the cooling chamber during cooling.

Therefore, it is considered that a configuration of the flash lamp annealer disclosed in US2014/0235072 is provided with two cooling chambers to transport semiconductor wafers alternately to these cooling chambers to suppress a decrease in the throughput and secure a sufficient nitrogen purge time, and decrease the oxygen concentration in the chambers. However, some treatment contents of a semiconductor wafer requests a cooling treatment at a lower oxygen concentration even though the throughput lowers more or less. On the other hand, a high throughput is demanded depending on treatment contents.

### SUMMARY OF THE INVENTION

The present invention is intended for a heat treatment apparatus for heating a substrate by irradiating the substrate with a flash of light.

According to one aspect of the present invention, the heat treatment apparatus includes: an indexer including a transfer robot, and for transporting an untreated substrate into the heat treatment apparatus and transporting a treated substrate out of the heat treatment apparatus; a transport chamber including a transport robot; a first cooling chamber connected to the transport chamber and the indexer; a second cooling chamber connected to the transport chamber and the indexer; a treatment chamber connected to the transport chamber; a flash lamp for heating the substrate by irradiating the substrate received in the treatment chamber, with a flash of light; and a controller for controlling the transfer robot and the transport robot, wherein the controller controls the transfer robot and the transport robot with the controller switched to one of a high throughput mode of transporting an untreated first substrate from the indexer into the first cooling chamber, supplying nitrogen gas into the first cooling chamber, replacing an inside of the first cooling chamber with a nitrogen atmosphere, then transporting the first substrate from the first cooling chamber to the treatment chamber via the transport chamber, transferring the first substrate subjected to a heating treatment from the treatment chamber to the first cooling chamber via the transport chamber, cooling the first substrate, then transporting the first substrate out to the indexer, transporting an untreated second substrate from the indexer into the second cooling chamber, supplying the nitrogen gas into the second cooling chamber, replacing an inside of the second cooling chamber with the nitrogen atmosphere, then transporting the second substrate from the second cooling chamber into the treatment chamber via the transport chamber, transferring the second substrate subjected to the heating treatment from the treatment chamber to the second cooling chamber via the transport chamber, cooling the second substrate, and then transporting the second substrate out to the indexer, and a low oxygen concentration mode of transporting an untreated substrate from the indexer into the first cooling chamber, supplying the nitrogen gas into the first cooling chamber, replacing the inside of the first cooling chamber with the nitrogen atmosphere, then transporting the substrate from the first cooling chamber into the treatment chamber via the transport chamber, transferring the substrate subjected to the heating treatment from the treatment chamber to the second cooling chamber via the transport chamber, cooling the substrate, and then transporting the substrate out to the indexer via the transport chamber and the first cooling chamber.

The controller is switched to one of the high throughput mode and the low oxygen concentration mode to control the transfer robot and the transport robot. Consequently, it is possible to use a treatment with a high throughput and a cooling treatment at a low oxygen concentration as appropriate.

The present invention is also intended for a heat treatment method for heating a substrate by irradiating the substrate with a flash of light.

According to one aspect of the present invention, a substrate is transported while one of two modes is selected, the modes comprising a high throughput mode of transporting an untreated first substrate from an indexer into a first cooling chamber, supplying nitrogen gas into the first cooling chamber, replacing an inside of the first cooling chamber with a nitrogen atmosphere, then transporting the first substrate from the first cooling chamber into a treatment chamber via a transport chamber, heating the first substrate in the treatment chamber by irradiating the first substrate with the flash of light, then transferring the first substrate from the treatment chamber to the first cooling chamber via the transport chamber, cooling the first substrate, then transporting the first substrate out to the indexer, transporting an untreated second substrate from the indexer into a second cooling chamber, supplying the nitrogen gas into the second cooling chamber, replacing an inside of the second cooling chamber with the nitrogen atmosphere, then transporting the second substrate from the second cooling chamber into the treatment chamber via the transport chamber, heating the second substrate in the treatment chamber by irradiating the second substrate with the flash of light, then transferring the second substrate from the treatment chamber to the second cooling chamber via the transport chamber, cooling the second substrate, and then transporting the second substrate out to the indexer, and a low oxygen concentration mode of transporting an untreated substrate from the indexer into the first cooling chamber, supplying the nitrogen gas into the first cooling chamber, replacing the inside of the first cooling chamber with the nitrogen atmosphere, then transporting the substrate from the first cooling chamber into the treatment chamber via the transport chamber, heating the substrate in the treatment chamber by irradiating the substrate with the flash of light, then transferring the substrate from the treatment chamber to the second cooling chamber via the transport chamber, cooling the substrate, and then transporting the substrate out to the indexer via the transport chamber and the first cooling chamber.

Since the substrate is transported while one of the high throughput mode and the low oxygen concentration mode is selected, it is possible to use a treatment with a high throughput and a cooling treatment at a low oxygen concentration as appropriate.

It is therefore an object of the present invention is to use the treatment with a high throughput and the cooling treatment at a low oxygen concentration separately as appropriate.

These and other objects, features, aspects and advantages of the present invention will become more apparent from the following detailed description of the present invention when taken in conjunction with the accompanying drawings.

### BRIEF DESCRIPTION OF THE DRAWING

FIG. 1 is a plan view showing a heat treatment apparatus according to the present invention;

FIG. 2 is a front view of the heat treatment apparatus in FIG. 1;

FIG. 3 is a longitudinal cross-sectional view showing a configuration of a heat treatment part;

FIG. 4 is a perspective view showing an entire external appearance of a holder;

FIG. 5 is a plan view of a susceptor;

FIG. 6 is a cross-sectional view of the susceptor;

FIG. 7 is a plan view of a transfer mechanism;

FIG. 8 is a side view of the transfer mechanism;

FIG. 9 is a plan view showing an arrangement of a plurality of halogen lamps;

FIG. 10 is a view showing a configuration of a cooler;

FIG. 11 is a view showing transport paths of a semiconductor wafer according to a “high throughput mode”;

FIG. 12 is a view showing a transport path of a semiconductor wafer according to a “low oxygen concentration mode”;

FIG. 13 is a view showing a transport path of a semiconductor wafer according to a “contamination inspection mode”; and

FIG. 14 is a view showing a transport path of a semiconductor wafer according to a “reflectance measurement mode”.

### DESCRIPTION OF THE PREFERRED EMBODIMENTS

Preferred embodiments according to the present invention will now be described in detail with reference to the drawings.

### First Preferred Embodiment

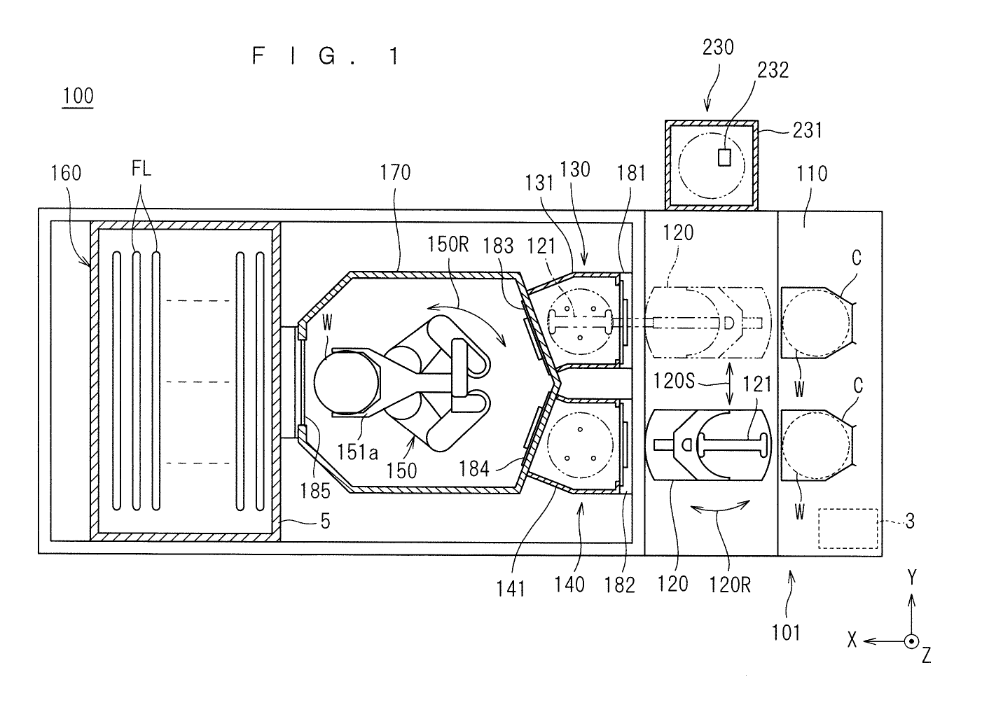

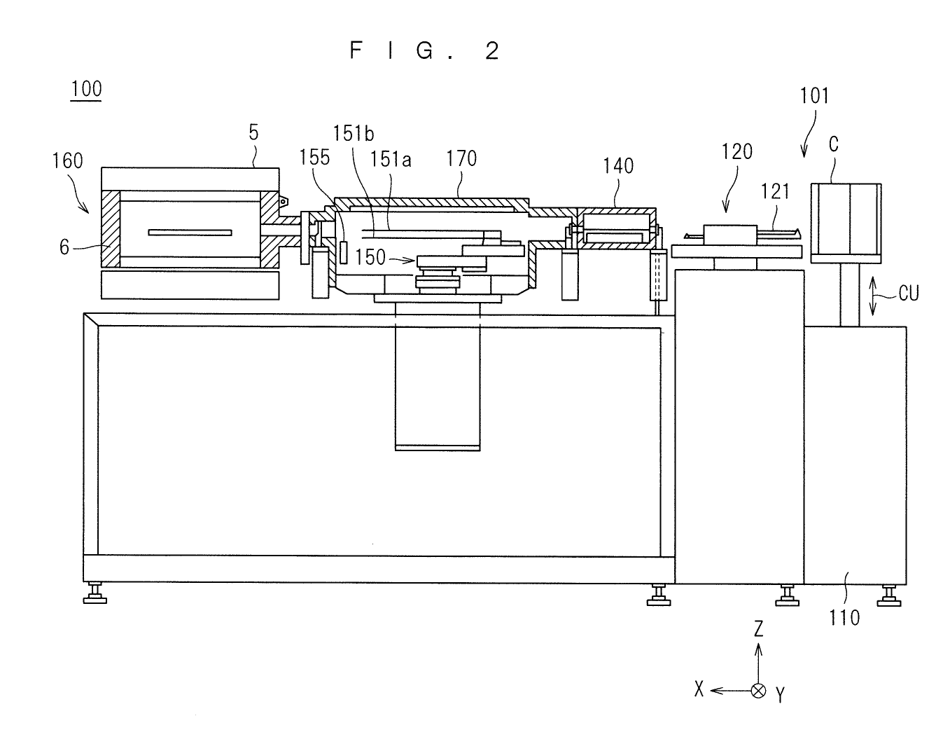

First, an entire schematic configuration of a heat treatment apparatus 100 according to the present invention will be described. FIG. 1 is a plan view showing the heat treatment apparatus 100 according to the present invention. FIG. 2 is a front view of the heat treatment apparatus 100. The heat treatment apparatus 100 is a flash lamp annealer for heating a disk-shaped semiconductor wafer W serving as a substrate by irradiating the semiconductor wafer W with flashes of light. The size of the semiconductor wafer W to be treated is not particularly limited. For example, the semiconductor wafer W to be treated has a diameter of 300 mm or 450 mm. The semiconductor wafer W prior to the transport into the heat treatment apparatus 100 is implanted with impurities. The heat treatment apparatus 100 performs a heating treatment on the semiconductor wafer W to thereby activate the impurities implanted in the semiconductor wafer W. It should be noted that the dimensions of components and the number of components are shown in exaggeration or in simplified form, as appropriate, in FIG. 1 and the subsequent figures for the sake of easier understanding. Further, each of FIGS. 1 to 3 shows an XYZ orthogonal coordinate system whose Z axis direction is a vertical direction and whose XY plane is a horizontal plane to clarify a direction relationship between the drawings.

As shown in FIGS. 1 and 2, the heat treatment apparatus 100 includes an indexer 101 for transporting the untreated semiconductor wafer W from an outside into the heat treatment apparatus 100 and transporting the treated semiconductor wafer W out of the heat treatment apparatus 100, an alignment part 230 for positioning the untreated semiconductor wafer W, two coolers 130 and 140 for cooling the semiconductor wafer W subjected to the heating treatment, a heat treatment part 160 for performing a flash heating treatment on the semiconductor wafer W, and a transport robot 150 for transferring the semiconductor wafer W to and from the coolers 130 and 140 and the heat treatment part 160. Further, the heat treatment apparatus 100 includes a controller 3 for controlling an operation mechanism provided in each of the above treatment parts, and the transport robot 150 to advance the flash heating treatment of the semiconductor wafer W.

The indexer 101 includes a load port 110 for aligning and placing a plurality of (in the present preferred embodiment, two) carriers C, and a transfer robot 120 for taking out the untreated semiconductor wafer W from each carrier C and housing the treated semiconductor wafer W in each carrier C. The carrier C having received the untreated semiconductor wafer W is transported by an unmanned transport vehicle (an AGV or an OHT) and is placed on the load port 110. The carrier C having received the treated semiconductor wafer W is carried away from the load port 110 by the unmanned transport vehicle.

Further, the load port 110 is configured to be able to upwardly and downwardly move the carrier C as indicated by an arrow CU in FIG. 2 such that the transfer robot 120 can transport any semiconductor wafer W into and out of the carrier C. In addition, a form of the carrier C may be a front opening unified pod (FOUP) for receiving the semiconductor wafer W in an enclosed space, and, in addition, a standard mechanical interface (SMIF) pod or an open cassette (OC) for exposing the received semiconductor wafer W to outdoor air.

Further, the transfer robot 120 can perform slide movement indicated by an arrow 120S in FIG. 1, and a turning operation indicated by an arrow 120R and an upward/downward movement operation. By this means, the transfer robot 120 transports the semiconductor wafer W into and out of the two carriers C, and transfers the semiconductor wafer W to and from the alignment part 230 and the two coolers 130 and 140. The transfer robot 120 transports the semiconductor wafer W into and out of the carrier C by sliding and moving a hand 121 and moving the carrier C upwardly and downwardly. Further, the transfer robot 120 transfers the semiconductor wafer W to and from the alignment part 230 or the coolers 130 and 140 by sliding and moving the hand 121 and operating the transfer robot 120 to move upwardly and downwardly.

The alignment part 230 is connected to a side of the indexer 101 along a Y axis direction. The alignment part 230 is a treatment part for rotating the semiconductor wafer W in the horizontal plane, and directing the semiconductor wafer W in a direction suitable for flash heating. The alignment part 230 includes, inside an alignment chamber 231 that is an enclosure made of an aluminum alloy, a mechanism for supporting the semiconductor wafer W in a horizontal attitude and rotating the semiconductor wafer W, and a mechanism for optically detecting, for example, a notch or an orientation flat formed at a peripheral portion of the semiconductor wafer W. Further, the alignment chamber 231 is provided with a reflectance measurement part 232 for measuring a reflectance of a surface of the semiconductor wafer W supported therein. The reflectance measurement part 232 irradiates the surface of the semiconductor wafer W with light of a predetermined wavelength, receives reflected light reflected from the surface, and measures the reflectance of the surface of the semiconductor wafer W based on an intensity of this reflected light.

The semiconductor wafer W is transferred to and from the alignment part 230 by the transfer robot 120. The semiconductor wafer W is transferred from the transfer robot 120 to the alignment chamber 231 such that a wafer center is located at a predetermined position. The alignment part 230 rotates the semiconductor wafer W around a vertical direction axis about a rotation center that is a center portion of the semiconductor wafer W received from the indexer 101, and optically detects, for example, a notch to adjust a direction of the semiconductor wafer W. The reflectance measurement part 232 measures the reflectance of the surface of the semiconductor wafer W. The semiconductor wafer W whose direction has been adjusted is taken out of the alignment chamber 231 by the transfer robot 120.

As a transport space of the semiconductor wafer W in the transport robot 150, a transport chamber 170 for housing the transport robot 150 is provided. Three sides of this transport chamber 170 are connected in communication with a treatment chamber 6 of the heat treatment part 160, a first cooling chamber 131 of the cooler 130 and a second cooling chamber 141 of the cooler 140.

The heat treatment part 160 that is a main part of the heat treatment apparatus 100 is a substrate treatment part for performing a flash heating treatment on the preheated semiconductor wafer W by irradiating the semiconductor wafer W with a flash (a flash of light) from xenon flash lamps FL. A configuration of the heat treatment part 160 will be described in more detail below.

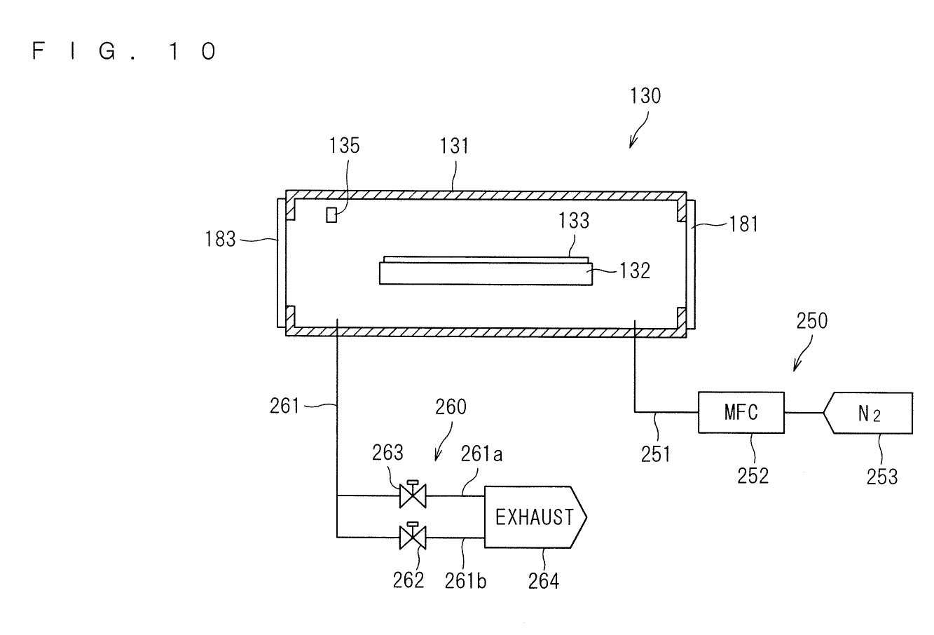

The two coolers 130 and 140 employ the substantially same configuration. FIG. 10 is a view showing a configuration of the cooler 130. The cooler 130 includes a metal cooling plate 132 inside the first cooling chamber 131 (cooling chamber) that is an enclosure made of an aluminum alloy. A quartz plate 133 is placed on an upper surface of the cooling plate 132. A temperature of the cooling plate 132 is adjusted to a normal temperature (approximately 23° C.) by a Peltier element or constant temperature water circulation. When the semiconductor wafer W subjected to the flash heating treatment in the heat treatment part 160 is transported into the first cooling chamber 131, the semiconductor wafer W is placed on the quartz plate 133 and cooled. In the first cooling chamber 131, an oximeter 135 for measuring an oxygen concentration of an internal space of the first cooling chamber 131 is installed.

The first cooling chamber 131 is connected to and between both of the indexer 101 and the transport chamber 170. The first cooling chamber 131 is provided with two openings formed for transporting the semiconductor wafer W in and out. The opening of the two openings connected to the indexer 101 is openable and closable by a gate valve 181. The opening connected to the transport chamber 170 is openable and closable by a gate valve 183. In other words, the first cooling chamber 131 and the indexer 101 are connected with the gate valve 181 interposed therebetween, and the first cooling chamber 131 and the transport chamber 170 are connected with the gate valve 183 interposed therebetween.

When the semiconductor wafer W is transferred between the indexer 101 and the first cooling chamber 131, the gate valve 181 is opened. When the semiconductor wafer W is transferred between the first cooling chamber 131 and the transport chamber 170, the gate valve 183 is opened. When the gate valve 181 and the gate valve 183 are closed, the inside of the first cooling chamber 131 is an enclosed space.

The cooler 130 is provided with a gas supply part 250 for supplying nitrogen gas (N₂) into the first cooling chamber 131, and an exhaust part 260 for exhausting the gas from the first cooling chamber 131. The gas supply part 250 includes a supply pipe 251, a mass flow controller 252, and a nitrogen gas supply source 253. A distal end of the supply pipe 251 is connected to the first cooling chamber 131, and a base end is connected to the nitrogen gas supply source 253. The mass flow controller 252 is provided at some midpoint of the supply pipe 251. The mass flow controller 252 can adjust a flow rate of the nitrogen gas supplied from the nitrogen gas supply source 253 to the first cooling chamber 131, and switches between a large supply flow rate (e.g., 120 liters/minute) and a small supply flow rate (e.g., 20 liters/minute) in the present preferred embodiment. In other words, the gas supply part 250 supplies the nitrogen gas at the large supply flow rate or the small supply flow rate into the first cooling chamber 131.

The exhaust part 260 includes an exhaust pipe 261, a main valve 263, an auxiliary valve 262, and an exhaust mechanism 264. A distal end of the exhaust pipe 261 is connected to the first cooling chamber 131, and a base end is connected to the exhaust mechanism 264. A base end side of the exhaust pipe 261 is branched into two of a main exhaust pipe 261a and an auxiliary exhaust pipe 261b.These main exhaust pipe 261a and the auxiliary exhaust pipe 261b are connected to the exhaust mechanism 264. The main valve 263 is provided at some midpoint in the main exhaust pipe 261a. The auxiliary valve 262 is provided at some midpoint in the auxiliary exhaust pipe 261b.

The main exhaust pipe 261a and the auxiliary exhaust pipe 261b have different pipe diameters. The pipe diameter of the main exhaust pipe 261a is larger than the pipe diameter of the auxiliary exhaust pipe 261b. In other words, an exhaust path employing the main exhaust pipe 261a and an exhaust path employing the auxiliary exhaust pipe 261b have different exhaust conductance. In the present preferred embodiment, while the auxiliary valve 262 is opened at all times, the main valve 263 is switched to open and close as appropriate. When both of the main valve 263 and the auxiliary valve 262 are opened, an atmosphere in the first cooling chamber 131 is exhausted at a large exhaust flow rate. When the main valve 263 is closed and only the auxiliary valve 262 is opened, the atmosphere in the first cooling chamber 131 is exhausted at a small exhaust flow rate. In other words, the exhaust part 260 exhausts the atmosphere at the large exhaust flow rate or the small exhaust flow rate from the first cooling chamber 131. The nitrogen gas supply source 253 and the exhaust mechanism 264 may be mechanisms provided in the heat treatment apparatus 100 or be utility systems in a factory in which the heat treatment apparatus 100 is installed.

The cooler 140 also employs the substantially same configuration as that of the cooler 130. In other words, the cooler 140 includes, inside the second cooling chamber 141 that is an enclosure made of an aluminum alloy, a metal cooling plate, and a quartz plate placed on an upper surface of the cooling plate. The second cooling chamber 141 and the indexer 101 are connected with a gate valve 182 interposed therebetween, and the second cooling chamber 141 and the transport chamber 170 are connected with a gate valve 184 interposed therebetween (FIG. 1). The cooler 140 also includes the same supply/exhaust mechanism as those of the above gas supply part 250 and exhaust part 260.

The transport robot 150 provided in the transport chamber 170 is turnable about an axis along the vertical direction as indicated by an arrow 150R. The transport robot 150 includes two linkage mechanisms including a plurality of arm segments. Distal ends of the two linkage mechanisms are respectively provided with transport hands 151a and 151b for holding the semiconductor wafer W. The transport hands 151a and 151b are disposed vertically spaced a predetermined pitch apart from each other, and are linearly slidable by the linkage mechanisms in the same horizontal direction independently from each other. The transport robot 150 moves upwardly and downwardly a base provided with the two linkage mechanisms to move the two transport hands 151a and 151b upwardly and downwardly in a state where the two transport hands 151a and 151b are spaced the predetermined pitch apart.

When the transport robot 150 transfers (transports) the semiconductor wafer W to or from the first cooling chamber 131, the second cooling chamber 141 or the treatment chamber 6 of the heat treatment part 160 as a transfer party, both of the transport hands 151a and 151b first turn to face the transfer party, and then (or during the turn) move upwardly and downwardly to reach a height for transferring the semiconductor wafer W between one of the transport hands and the transfer party. The transport hand 151a (151b) is linearly slid and moved in the horizontal direction to transfer the semiconductor wafer W to or from the transfer party.

The semiconductor wafer W can be transferred between the transport robot 150 and the transfer robot 120 via the coolers 130 and 140. That is, the first cooling chamber 131 of the cooler 130 and the second cooling chamber 141 of the cooler 140 also function as paths for transferring the semiconductor wafer W between the transport robot 150 and the transfer robot 120. More specifically, by transferring the semiconductor wafer W transferred by one of the transport robot 150 and the transfer robot 120 to the first cooling chamber 131 or the second cooling chamber 141 to the other one, the semiconductor wafer W is transferred.

As described above, the gate valves 181 and 182 are provided between the first cooling chamber 131 and the second cooling chamber 141, and the indexer 101, respectively. The gate valves 183 and 184 are provided between the transport chamber 170, and the first cooling chamber 131 and the second cooling chamber 141, respectively. A gate valve 185 is provided between the transport chamber 170 and the treatment chamber 6 of the heat treatment part 160. When the semiconductor wafer W is transported in the heat treatment apparatus 100, these gate valves are opened and closed as appropriate.

An oximeter 155 is provided in the transport chamber 170 (FIG. 2). The oximeter 155 measures the oxygen concentration in the transport chamber 170. Nitrogen gas is supplied into the transport chamber 170 and the alignment chamber 231, too, from a gas supply part, and atmospheres in the transport chamber 170 and the alignment chamber 231 are exhausted by an exhaust part (neither of the gas supply part and the exhaust part is shown).

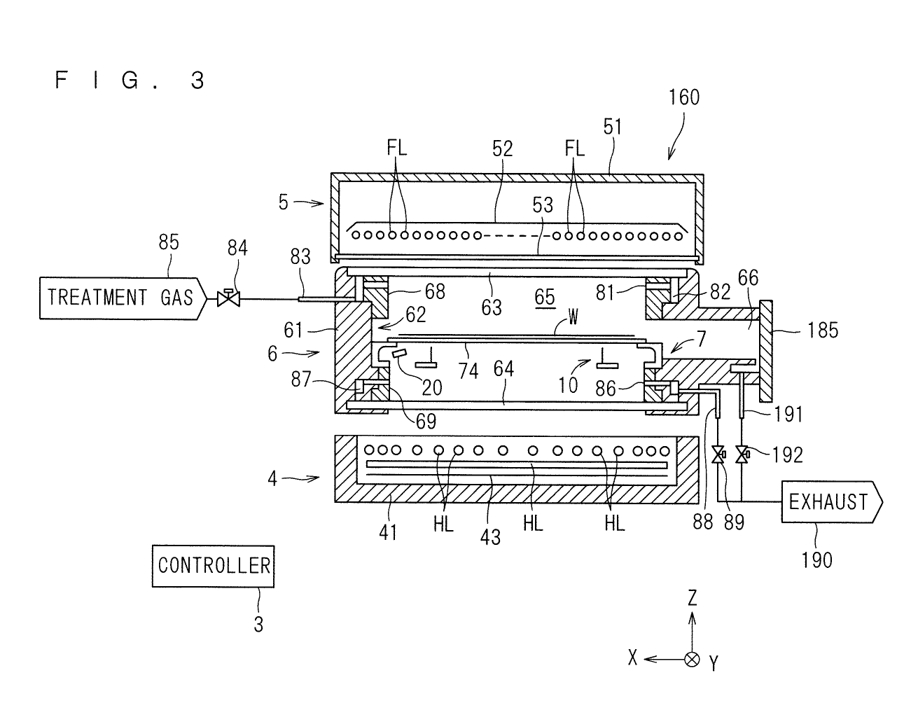

Next, a configuration of the heat treatment part 160 will be described. FIG. 3 is a longitudinal cross-sectional view showing the configuration of the heat treatment part 160. The heat treatment part 160 includes the treatment chamber 6 for receiving a semiconductor wafer W therein and performing a heating treatment, a flash lamp house 5 including a plurality of built-in flash lamps FL, and a halogen lamp house 4 including a plurality of built-in halogen lamps HL. The flash lamp house 5 is provided over the treatment chamber 6, and the halogen lamp house 4 is provided under the treatment chamber 6. The heat treatment part 160 further includes a holder 7 provided inside the treatment chamber 6 and for holding the semiconductor wafer W in a horizontal attitude, and a transfer mechanism 10 for transferring the semiconductor wafer W between the holder 7 and the transport robot 150.

The treatment chamber 6 is configured by mounting upper and lower chamber windows made of quartz to the top and bottom, respectively, of a tubular chamber side portion 61. The chamber side portion 61 has a generally tubular shape having an open top and an open bottom. An upper chamber window 63 is mounted to block the top opening of the chamber side portion 61, and a lower chamber window 64 is mounted to block the bottom opening thereof. The upper chamber window 63 forming the ceiling of the treatment chamber 6 is a disk-shaped member made of quartz, and serves as a quartz window that transmits flashes of light emitted from the flash lamps FL therethrough into the treatment chamber 6. The lower chamber window 64 forming the floor of the treatment chamber 6 is also a disk-shaped member made of quartz, and serves as a quartz window that transmits light emitted from the halogen lamps HL therethrough into the treatment chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the treatment chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the treatment chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the treatment chamber 6, and surrounds the holder 7 which holds the semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of the semiconductor wafer W therethrough into and out of the treatment chamber 6. The transport opening 66 is openable and closable by the gate valve 185. The transport opening 66 is connected in communication with an outer peripheral surface of the recessed portion 62. Thus, when the transport opening 66 is opened by the gate valve 185, the semiconductor wafer W is allowed to be transported through the transport opening 66 and the recessed portion 62 into and out of the heat treatment space 65. When the transport opening 66 is closed by the gate valve 185, the heat treatment space 65 in the treatment chamber 6 is an enclosed space.

At least one gas supply opening 81 for supplying a treatment gas therethrough into the heat treatment space 65 is provided in an upper portion of the inner wall of the treatment chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the treatment chamber 6. The gas supply pipe 83 is connected to a treatment gas supply source 85. A valve 84 is inserted at some midpoint in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen (N₂) gas, and reactive gases such as hydrogen (H₂) gas and ammonia (NH₃) gas (although nitrogen gas is used in this preferred embodiment).

At least one gas exhaust opening 86 for exhausting gas from the heat treatment space 65 is provided in a lower portion of the inner wall of the treatment chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the treatment chamber 6. The gas exhaust pipe 88 is connected to an exhaust mechanism 190. A valve 89 is inserted at some midpoint in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the treatment chamber 6, and may be in the form of slits. The treatment gas supply source 85 and the exhaust mechanism 190 may be mechanisms provided in the heat treatment apparatus 100 or be utility systems in a factory in which the heat treatment apparatus 100 is installed.

A gas exhaust pipe 191 for exhausting the gas from the heat treatment space 65 is also connected to a distal end of the transport opening 66. The gas exhaust pipe 191 is connected through a valve 192 to the exhaust mechanism 190. By opening the valve 192, the gas in the treatment chamber 6 is exhausted through the transport opening 66.

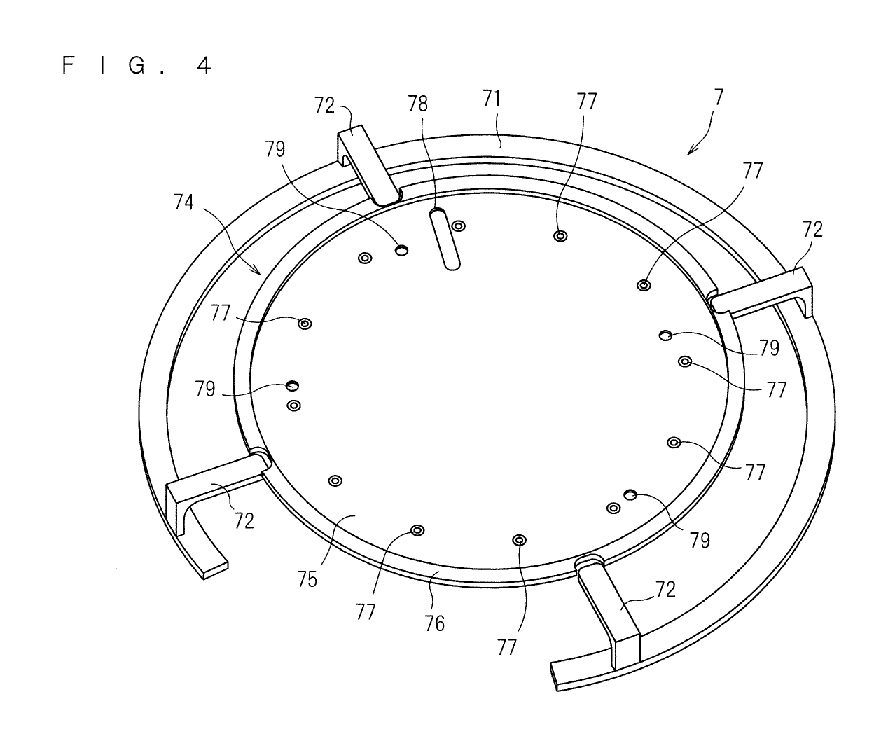

FIG. 4 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by a wall surface of the treatment chamber 6 by being placed on the bottom surface of the recessed portion 62 (with reference to FIG. 3). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

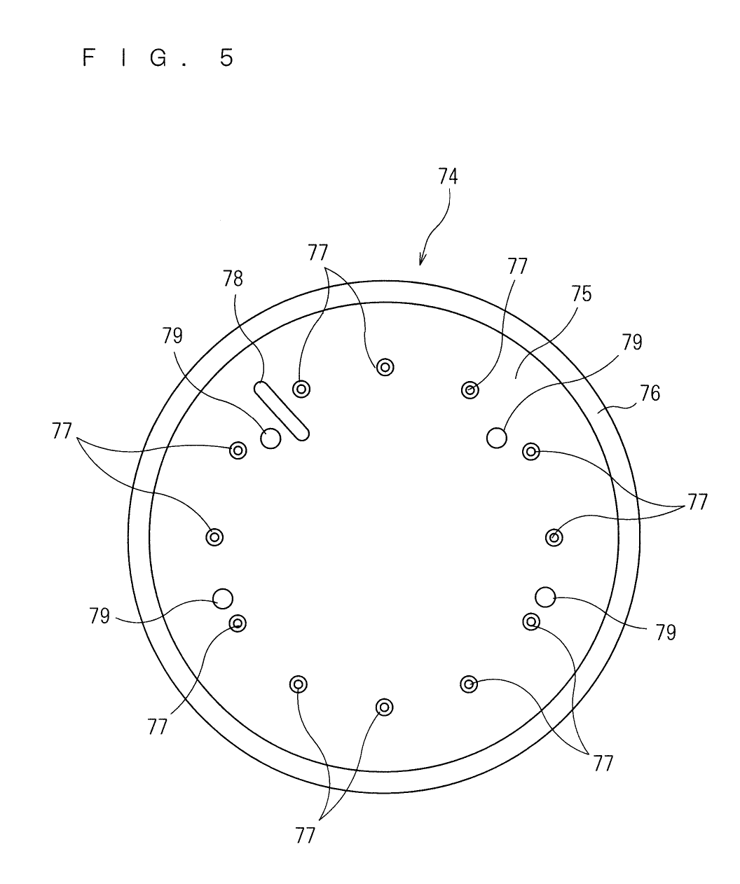

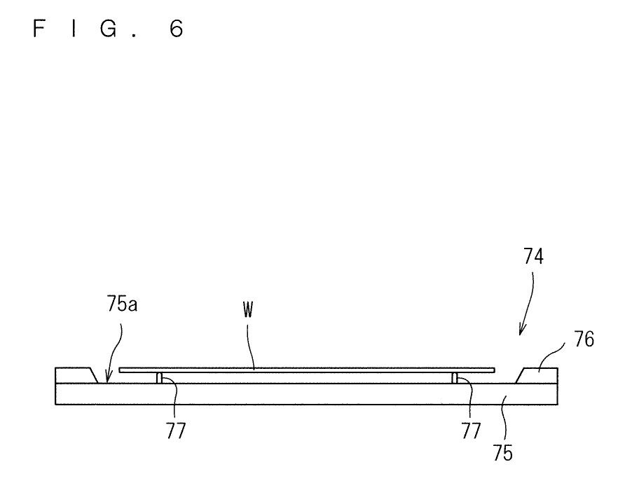

The susceptor 74 is supported by the four coupling portions 72 provided on the base ring 71. FIG. 5 is a plan view of the susceptor 74. FIG. 6 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of the semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 provided upright are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is slightly smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 4, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the treatment chamber 6, whereby the holder 7 is mounted to the treatment chamber 6. With the holder 7 mounted to the treatment chamber 6, the holding plate 75 of the susceptor 74 assumes a horizontal attitude (an attitude such that the normal to the susceptor 74 coincides with the vertical direction). In other words, the holding surface 75a of the holding plate 75 becomes a horizontal surface.

The semiconductor wafer W transported into the treatment chamber 6 is placed and held in a horizontal attitude on the susceptor 74 of the holder 7 mounted to the treatment chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 4 and 5, an opening 78 is formed in the holding plate 75 of the susceptor 74 so as to extend vertically through the holding plate 75 of the susceptor 74. The opening 78 is provided for a radiation thermometer 20 (see FIG. 3) to receive radiation (infrared radiation) emitted from the lower surface of the semiconductor wafer W supported by the susceptor 74. In other words, the radiation thermometer 20 receives the light emitted from the lower surface of the semiconductor wafer W held by the susceptor 74 through the opening 78, and an additionally installed detector measures the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer the semiconductor wafer W.

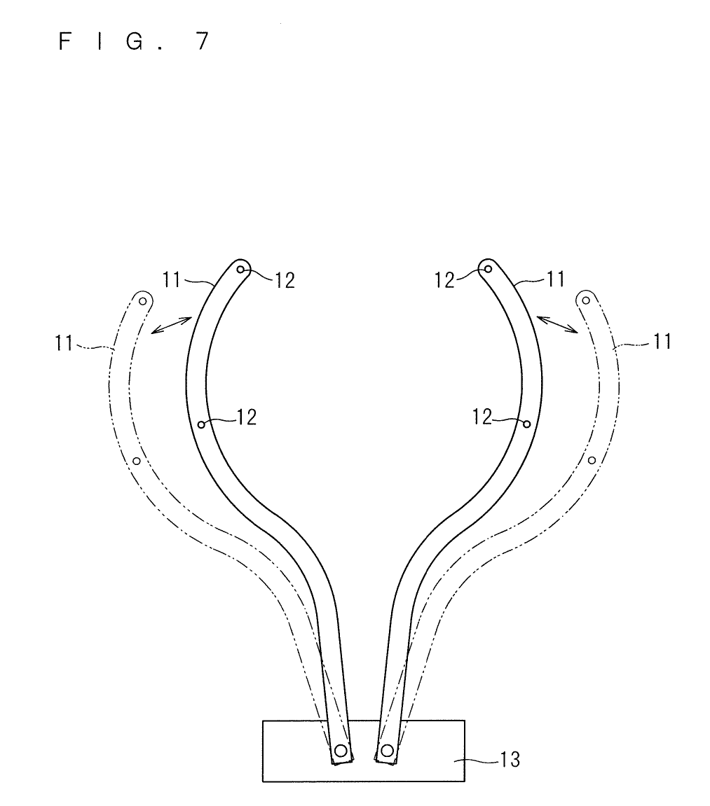

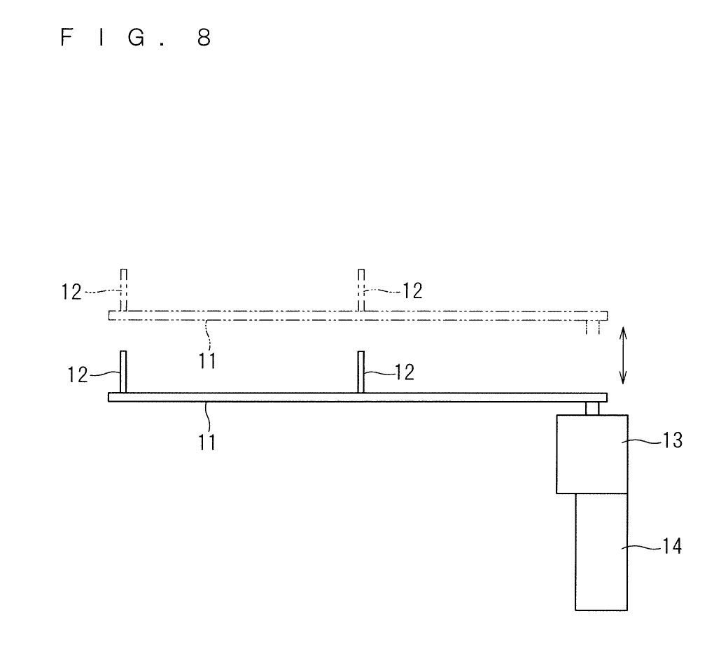

FIG. 7 is a plan view of the transfer mechanism 10. FIG. 8 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 are pivotable by a horizontal movement mechanism 13. The horizontal movement mechanism 13 moves the pair of transfer arms 11 horizontally between a transfer operation position (a position indicated by solid lines in FIG. 7) in which a semiconductor wafer W is transferred to and from the holder 7 and a retracted position (a position indicated by dash-double-dot lines in FIG. 7) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses the linkage mechanism to cause a single motor to pivot the pair of transfer arms 11 in cooperative relation.

The pair of transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 4 and 5) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the treatment chamber 6.

Referring again to FIG. 3, the flash lamp house 5 provided over the treatment chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash lamp house 5 further includes a lamp light radiation window 53 mounted to the bottom of the enclosure 51. The lamp light radiation window 53 forming the floor of the flash lamp house 5 is a plate-like quartz window made of quartz. The flash lamp house 5 is provided over the treatment chamber 6, whereby the lamp light radiation window 53 is opposed to the upper chamber window 63. The flash lamps FL direct flashes of light from over the treatment chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of the semiconductor wafer W held by the holder 7 (that is, in the horizontal direction). Thus, a plane defined by the arrangement of the flash lamps FL is also a horizontal plane.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. This xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen lamp house 4 provided under the treatment chamber 6 includes an enclosure 41 incorporating the multiple (in the present preferred embodiment, 40) halogen lamps HL. The halogen lamps HL direct light from under the treatment chamber 6 through the lower chamber window 64 toward the heat treatment space 65.

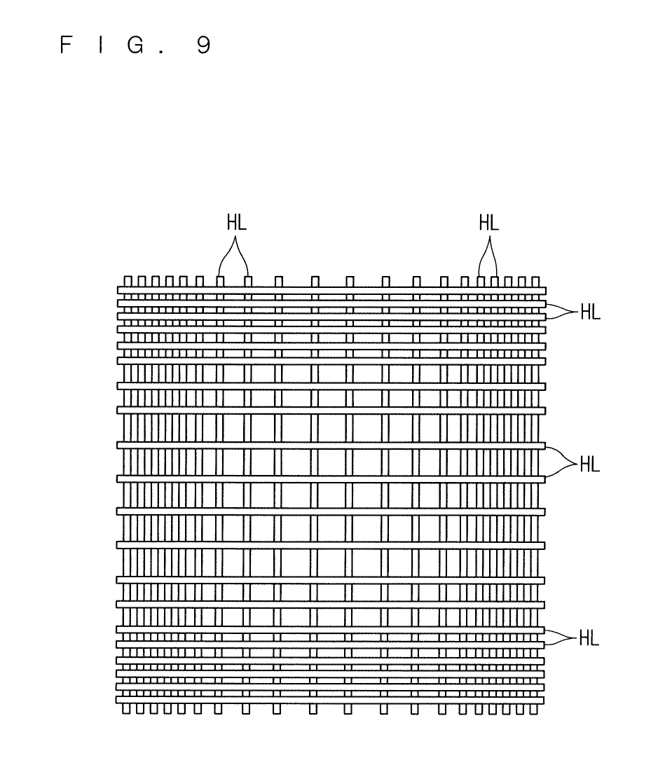

FIG. 9 is a plan view showing an arrangement of the multiple halogen lamps HL. In the present preferred embodiment, the 20 halogen lamps HL are disposed in each of two upper and lower tiers. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in the horizontal direction). Thus, a plane defined by the arrangement of the halogen lamps HL in each of the upper and lower tiers is also a horizontal plane.

As shown in FIG. 9, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in the peripheral portion of the lamp arrangement than in the central portion thereof. This allows a greater amount of light to impinge upon the peripheral portion of the semiconductor wafer W where a temperature decrease is prone to occur when the semiconductor wafer W is heated by the irradiation thereof with light from the halogen lamps HL.

The group of halogen lamps HL in the upper tier and the group of halogen lamps HL in the lower tier are arranged to intersect each other in a lattice pattern. In other words, the 40 halogen lamps HL in total are disposed so that the longitudinal direction of each halogen lamp HL arranged in the upper tier and the longitudinal direction of each halogen lamp HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. Thus, the halogen lamps HL are continuous lighting lamps that emit light continuously for at least not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen lamp house 4 under the halogen lamps HL arranged in two tiers (FIG. 3). The reflector 43 reflects the light emitted from the halogen lamps HL toward the heat treatment space 65.

The heat treatment part 160 further includes, in addition to the aforementioned components, various cooling structures to prevent an excessive temperature rise in the halogen lamp house 4, the flash lamp house 5 and the treatment chamber 6 because of the heat energy generated from the halogen lamps HL and the flash lamps FL during the heat treatment of the semiconductor wafer W. As an example, a water cooling tube (not shown) is provided in the walls of the treatment chamber 6. Also, the halogen lamp house 4 and the flash lamp house 5 have an air cooling structure for forming a gas flow therein to exhaust heat. Air is supplied to a gap between the upper chamber window 63 and the lamp light radiation window 53 to cool down the flash lamp house 5 and the upper chamber window 63.

The controller 3 controls the aforementioned various operating mechanisms provided in the heat treatment apparatus 100. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like therein. The CPU in the controller 3 executes a predetermined processing program, whereby the processes in the heat treatment apparatus 100 proceed. Although FIG. 1 shows the controller 3 in the indexer 101, the controller 3 is not limited to this, and can be arranged at any position in the heat treatment apparatus 100.

Next, a treatment operation of the semiconductor wafer W in the heat treatment apparatus 100 according to the present invention will be described. The semiconductor wafer W to be treated herein is a semiconductor substrate doped with impurities (ions) by an ion implantation process. The impurities are activated by the heat treatment apparatus 100 performing the process of heating (annealing) the semiconductor wafer W by irradiation with a flash of light. Hereinafter, a rough transport procedure of the semiconductor wafer W in the heat treatment apparatus 100, and a heating treatment of the semiconductor wafer W in the heat treatment part 160 will be described.

First, a plurality of untreated semiconductor wafers W implanted with impurities and received in the carriers C is placed on the load port 110 of the indexer 101. The transfer robot 120 takes out the untreated semiconductor wafers W one by one from the carrier C to transport the semiconductor wafers W into the alignment chamber 231 of the alignment part 230. The alignment part 230 rotates the semiconductor wafer W around the vertical direction axis about the rotation center that is the center portion of the semiconductor wafer W in the horizontal plane, and optically detects, for example, a notch to adjust a direction of the semiconductor wafer W. Then, the reflectance measurement part 232 may measure the reflectance of the surface of the semiconductor wafer W.

Next, the transfer robot 120 of the indexer 101 takes out the semiconductor wafer W whose direction has been adjusted, from the alignment chamber 231 to transport the semiconductor wafer W into the first cooling chamber 131 of the cooler 130 or the second cooling chamber 141 of the cooler 140. The untreated semiconductor wafer W transported into the first cooling chamber 131 or the second cooling chamber 141 is transported out to the transport chamber 170 by the transport robot 150. When the untreated semiconductor wafer W is transported from the indexer 101 to the transport chamber 170 via the first cooling chamber 131 or the second cooling chamber 141, the first cooling chamber 131 and the second cooling chamber 141 function as the paths for transferring the semiconductor wafer W.

The transport robot 150 having taken out the semiconductor wafer W turns to face toward the heat treatment part 160. Subsequently, the gate valve 185 opens between the treatment chamber 6 and the transport chamber 170, and the transport robot 150 transports the untreated semiconductor wafer W into the treatment chamber 6. At this time, if the preceding semiconductor wafer W subjected to the heating treatment is in the treatment chamber 6, one of the transport hands 151a and 151b takes out the semiconductor wafer W subjected to the heating treatment and then the untreated semiconductor wafer W is transported into the treatment chamber 6, whereby the wafers are replaced. Subsequently, the gate valve 185 closes between the treatment chamber 6 and the transport chamber 170.

The semiconductor wafer W transported into the treatment chamber 6 is preheated by the halogen lamps HL, and then is subjected to the flash heating treatment by flash irradiation from the flash lamps FL. This flash heating treatment activates the impurities.

After the flash heating treatment is finished, the gate valve 185 opens between the treatment chamber 6 and the transport chamber 170 again, and the transport robot 150 transports the semiconductor wafer W subjected to the flash heating treatment out of the treatment chamber 6 to the transport chamber 170. The transport robot 150 having taken out the semiconductor wafer W turns to face toward the first cooling chamber 131 or the second cooling chamber 141 from the treatment chamber 6. The gate valve 185 closes between the treatment chamber 6 and the transport chamber 170.

Subsequently, the transport robot 150 transports the semiconductor wafer W subjected to the heating treatment into the first cooling chamber 131 of the cooler 130 and the second cooling chamber 141 of the cooler 140. The first cooling chamber 131 or the second cooling chamber 141 performs a cooling treatment on the semiconductor wafer W subjected to the flash heating treatment. At a point in time when the semiconductor wafer W is transported out of the treatment chamber 6 of the heat treatment part 160, the temperature of the entire semiconductor wafer W is relatively high, and therefore is cooled to approximately a room temperature by the first cooling chamber 131 or the second cooling chamber 141. After a predetermined cooling treatment time passes, the transfer robot 120 transports the cooled semiconductor wafer W out of the first cooling chamber 131 or the second cooling chamber 141 to return the semiconductor wafer W to the carrier C. After the carrier C receives a predetermined number of treated semiconductor wafers W, this carrier C is transported out of the load port 110 of the indexer 101. A transport path of the semiconductor wafer W in the heat treatment apparatus 100 will be described in more detail below.

The flash heating treatment in the heat treatment part 160 will continue to be described. Prior to transportation of the semiconductor wafer W into the treatment chamber 6, the valve 84 is opened for supply of gas, and the valves 89 and 192 for exhaust of gas are opened, so that the supply and exhaust of gas into and out of the treatment chamber 6 start. When the valve 84 is opened, nitrogen gas is supplied through the gas supply opening 81 into the heat treatment space 65. When the valve 89 is opened, the gas within the treatment chamber 6 is exhausted through the gas exhaust opening 86. This causes the nitrogen gas supplied from an upper portion of the heat treatment space 65 in the treatment chamber 6 to flow downwardly and then to be exhausted from a lower portion of the heat treatment space 65.

The gas within the treatment chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of the semiconductor wafer W in the heat treatment part 160. The amount of nitrogen gas supplied into the heat treatment space 65 is changed as appropriate in accordance with process steps.

Subsequently, the gate valve 185 is opened to open the transport opening 66. The transport robot 150 transports the semiconductor wafer W to be treated through the transport opening 66 into the heat treatment space 65 of the treatment chamber 6. The transport robot 150 causes the transport hand 151a (or the transport hand 151b) that holds the untreated semiconductor wafer W to move forward to a position immediately over the holder 7 and stop. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the untreated semiconductor wafer W is placed on the lift pins 12, the transport robot 150 moves the transport hand 151a out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof patterned and implanted with impurities is the upper surface. A predetermined distance is defined between the back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held in a horizontal attitude from below by the susceptor 74 of the holder 7, the 40 halogen lamps HL turn on simultaneously to start preheating (or assist-heating). Halogen light emitted from the halogen lamps HL is transmitted through the lower chamber window 64 and the susceptor 74 both made of quartz, and impinges from the lower surface of the semiconductor wafer W. By receiving halogen light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured with the radiation thermometer 20 when the halogen lamps HL perform the preheating. Specifically, the radiation thermometer 20 receives infrared radiation emitted from the lower surface of the semiconductor wafer W held by the susceptor 74 through the opening 78 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured with the radiation thermometer 20. The preheating temperature T1 shall be on the order of 600° C. to 800° C. (in the present preferred embodiment, 700° C.) at which there is no apprehension that the impurities implanted in the semiconductor wafer W are diffused by heat.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured with the radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in the peripheral portion thereof where heat dissipation is liable to occur than in the central portion thereof. However, the halogen lamps HL in the halogen lamp house 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

At a point in time when a predetermined time period has elapsed since the temperature of the semiconductor wafer W reaches the preheating temperature T1, the flash lamps FL irradiate the upper surface of the semiconductor wafer W with a flash of light. At this time, part of the flash of light emitted from the flash lamps FL travels directly toward the interior of the treatment chamber 6. The remainder of the flash of light is reflected once from the reflector 52, and then travels toward the interior of the treatment chamber 6. The irradiation of the semiconductor wafer W with such flashes of light achieves the flash heating of the semiconductor wafer W.

The flash heating, which is achieved by the emission of a flash of light from the flash lamps FL, is capable of increasing the temperature of the front surface of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The temperature of the upper surface of the semiconductor wafer W subjected to the flash heating by the flash irradiation from the flash lamps FL momentarily increases to a treatment temperature T2 of 1000° C. or higher. After the impurities implanted in the semiconductor wafer W are activated, the temperature of the upper surface of the semiconductor wafer W decreases rapidly. Because of the capability of increasing and decreasing the temperature of the upper surface of the semiconductor wafer W in an extremely short time, it is possible to activate the impurities implanted in the semiconductor wafer W while suppressing the diffusion of the impurities due to heat. It should be noted that the time required for the activation of the impurities is extremely short as compared with the time required for the thermal diffusion of the impurities. Thus, the activation is completed in a short time ranging from about 0.1 to about 100 milliseconds during which no diffusion occurs.

After a predetermined time period has elapsed since the completion of the flash heating treatment, the halogen lamps HL turn off. This causes the temperature of the semiconductor wafer W to decrease rapidly from the preheating temperature T1. The radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement with the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, when the transport opening 66 closed by the gate valve 185 is opened, the treated semiconductor wafer W placed on the lift pins 12 is transported out by the transport hand 151b (or the transport hand 151a) of the transport robot 150. The transport robot 150 causes the transport hand 151b to proceed and stop at a position immediately below the semiconductor wafer W lifted by the lift pins 12. When the pair of transfer arms 11 lowers, the semiconductor wafer W subjected to the flash heating is transferred to the transport hand 151b and is placed. Subsequently, the transport robot 150 moves the transport hand 151b out of the treatment chamber 6, and transports the treated semiconductor wafer W out.

In the first preferred embodiment, two transport modes of the semiconductor wafer W in the heat treatment apparatus 100 are set. The first transport mode is a “high throughput mode”, and the second transport mode is a “low oxygen concentration mode”. In the first preferred embodiment, the two transport modes are switchable. According to one of the transport modes, the controller 3 controls the transfer robot 120 and the transport robot 150.

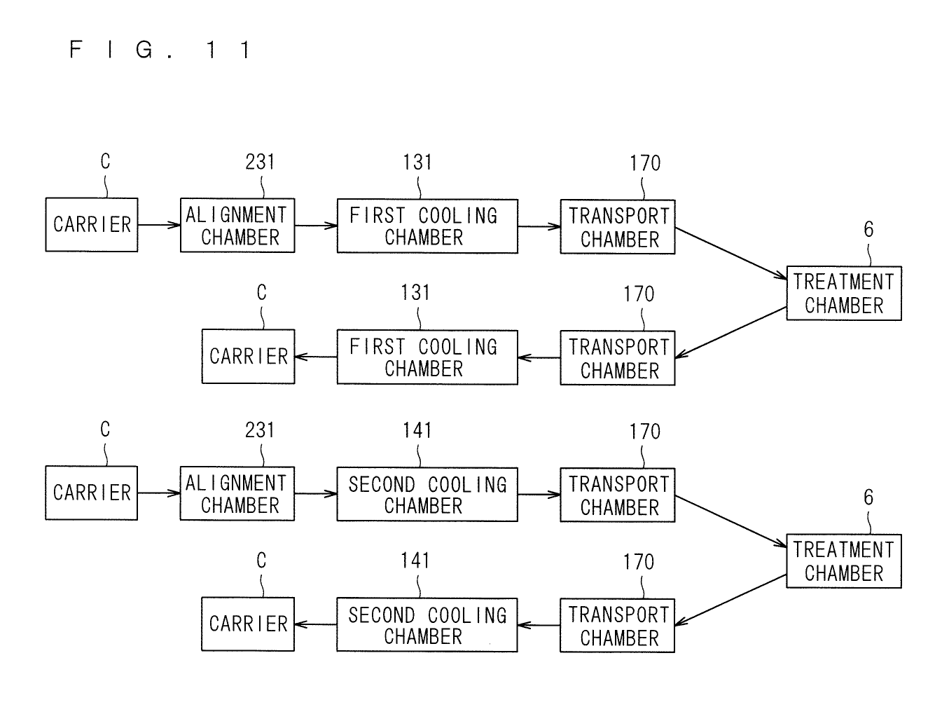

FIG. 11 is a view showing a transport path of the semiconductor wafer W according to the “high throughput mode”. In the “high throughput mode”, two transport paths are available. The two transport paths are different in that which one of the first cooling chamber 131 and the second cooling chamber 141 is used, and are the same regarding the rest of passage chambers.

First, a plurality of untreated semiconductor wafers W received in the carriers C is placed on the load port 110 of the indexer 101. The transfer robot 120 takes out the semiconductor wafers W one by one from the carrier C to transport the semiconductor wafers W into the alignment chamber 231 of the alignment part 230. Next, in the transport path shown in an upper tier in FIG. 11, the transfer robot 120 takes out the semiconductor wafer W whose direction has been adjusted, from the alignment chamber 231 to transport this semiconductor wafer W from the indexer 101 into the first cooling chamber 131 of the cooler 130. At a point in time when the semiconductor wafer W is transported into the first cooling chamber 131, the gate valve 181 closes between the first cooling chamber 131 and the indexer 101. The gate valve 183 closes between the first cooling chamber 131 and the transport chamber 170, too. Therefore, the inside of the first cooling chamber 131 is the enclosed space.

The first cooling chamber 131, which is originally for cooling the semiconductor wafer W, also functions as a path for transferring the semiconductor wafer W from the transfer robot 120 to the transport robot 150 in a first half of the transport path for transferring the semiconductor wafer W into the treatment chamber 6 of the heat treatment part 160. In this regard, since the indexer 101 is exposed to the air atmosphere, when the semiconductor wafer W is transported into the first cooling chamber 131, a large amount of the air atmosphere is mixed in the first cooling chamber 131, and the oxygen concentration in the first cooling chamber 131 rises up to approximately several percent. Therefore, opening the gate valve 183 as is causes rises in oxygen concentrations in the transport chamber 170 and, in addition, the treatment chamber 6. Therefore, for a predetermined time period after the semiconductor wafer W is transported into the first cooling chamber 131 and the gate valve 181 is closed, nitrogen gas is supplied at the large supply flow rate into the first cooling chamber 131 that is the enclosed space, and the atmosphere is exhausted at the large exhaust flow rate from the first cooling chamber 131. Consequently, the oxygen mixed in the first cooling chamber 131 as the semiconductor wafer W is transported in is quickly exhausted from the first cooling chamber 131, and the inside of the first cooling chamber 131 is replaced with a nitrogen atmosphere. As a result, the oxygen concentration having risen up to approximately several percent in the first cooling chamber 131 quickly lowers to 10 ppm or less. To reduce the air atmosphere mixed in as the semiconductor wafer W is transported in, the nitrogen gas may start being supplied at the large supply flow rate into the first cooling chamber 131 and the atmosphere may start being exhausted at the large exhaust flow rate from the first cooling chamber 131 a little before the semiconductor wafer W is transported into the first cooling chamber 131.

At a point in time when the predetermined time period passes after the semiconductor wafer W is transported into the first cooling chamber 131, a nitrogen gas supply flow rate for the first cooling chamber 131 is switched to the small supply flow rate, and an exhaust flow rate from the first cooling chamber 131 is switched to the small exhaust flow rate. It is concerned that, when the nitrogen gas supply flow rate for the first cooling chamber 131 is switched to the small supply flow rate, an air pressure in the first cooling chamber 131 becomes lower than the atmospheric pressure, and the air atmosphere of the indexer 101 leaks into the first cooling chamber 131. However, simultaneously, the nitrogen gas supply flow rate for the first cooling chamber 131 is switched to the small supply flow rate, and the exhaust flow rate from the first cooling chamber 131 is switched to the small exhaust flow rate. Consequently, the air pressure in the first cooling chamber 131 is maintained higher than the atmospheric pressure. Consequently, leakage of the air atmosphere from the indexer 101 to the first cooling chamber 131 is prevented.

Subsequently, the gate valve 183 opens between the first cooling chamber 131 and the transport chamber 170, and the transport robot 150 transports the semiconductor wafer W out of the first cooling chamber 131 to the transport chamber 170. The transport chamber 170 continues to be supplied with the nitrogen gas at all times, and has the nitrogen atmosphere inside. The transport robot 150 having taken out the semiconductor wafer W turns to face toward the heat treatment part 160. After the semiconductor wafer W is transported out, the gate valve 183 closes between the first cooling chamber 131 and the transport chamber 170.

Subsequently, the gate valve 185 opens between the treatment chamber 6 and the transport chamber 170, and the transport robot 150 transports the semiconductor wafer W into the treatment chamber 6. After the semiconductor wafer W is transported in, the gate valve 185 closes between the treatment chamber 6 and the transport chamber 170. The semiconductor wafer W transported into the treatment chamber 6 is preheated by the halogen lamps HL according to the above procedure, and then is subjected to the flash heating treatment by flash irradiation from the flash lamps FL.

After the flash heating treatment is finished, the gate valve 185 opens, and the transport robot 150 transports the semiconductor wafer W subjected to the flash heating treatment out of the treatment chamber 6 to the transport chamber 170. The transport robot 150 having taken out the semiconductor wafer W turns to face toward the first cooling chamber 131 of the cooler 130 from the treatment chamber 6. The gate valve 185 closes between the treatment chamber 6 and the transport chamber 170, and the gate valve 183 opens between the first cooling chamber 131 and the transport chamber 170. Subsequently, the transport robot 150 transports the semiconductor wafer W immediately after the flash heating, into the first cooling chamber 131. At this time, if a new untreated semiconductor wafer W is in the first cooling chamber 131, one of the transport hands 151a and 151b takes out the untreated semiconductor wafer W and the treated semiconductor wafer W is transported into the first cooling chamber 131, whereby the wafers are replaced.

After the semiconductor wafer W subjected to the flash heating is transported into the first cooling chamber 131, the gate valve 183 closes between the first cooling chamber 131 and the transport chamber 170. The first cooling chamber 131 performs a cooling treatment on the semiconductor wafer W subjected to the flash heating treatment. At a point in time when the semiconductor wafer W is transported from the treatment chamber 6 of the heat treatment part 160, the temperature of the entire semiconductor wafer W is relatively high, and therefore is cooled to approximately a room temperature by the first cooling chamber 131.

For a predetermined time period after the semiconductor wafer W subjected to the heating treatment is transported into the first cooling chamber 131 and the gate valve 183 is closed, the nitrogen gas is supplied at the small supply flow rate into the first cooling chamber 131 that is the enclosed space, and the atmosphere is exhausted at the small exhaust flow rate from the first cooling chamber 131. At a point in time when the predetermined time period passes, the nitrogen gas supply flow rate for the first cooling chamber 131 is switched to the large supply flow rate, and the exhaust flow rate from the first cooling chamber 131 is switched to the large exhaust flow rate. Simultaneously, the nitrogen gas supply flow rate for the first cooling chamber 131 is switched to the large supply flow rate, and the exhaust flow rate from the first cooling chamber 131 is switched to the large exhaust flow rate. Consequently, the air pressure in the first cooling chamber 131 is maintained lower than the air pressure in the transport chamber 170, and leakage of the atmosphere from the first cooling chamber 131 to the transport chamber 170 is prevented.

After the cooling treatment of the semiconductor wafer W is finished, the gate valve 181 opens between the first cooling chamber 131 and the indexer 101, and the transfer robot 120 transports the cooled semiconductor wafer W out of the first cooling chamber 131 to the indexer 101 to return the semiconductor wafer W to the carrier C. Subsequently, a new untreated semiconductor wafer W is transported from the indexer 101 into the first cooling chamber 131.

Next, in the transport path shown in a lower tier in FIG. 11, the transfer robot 120 transports the semiconductor wafer W taken out from the alignment chamber 231, from the indexer 101 into the second cooling chamber 141 of the cooler 140. The cooler 130 and the cooler 140 have the same function, and the second cooling chamber 141 performs the same nitrogen purge as that performed in the above first cooling chamber 131. In other words, at a point in time when the semiconductor wafer W is transported into the second cooling chamber 141, the gate valve 182 closes between the second cooling chamber 141 and the indexer 101. The gate valve 184 closes between the second cooling chamber 141 and the transport chamber 170, too. Therefore, the inside of the second cooling chamber 141 is the enclosed space.

The second cooling chamber 141, which is also originally for cooling the semiconductor wafer W, also functions as a path for transferring the semiconductor wafer W from the transfer robot 120 to the transport robot 150 in a first half of the transport path for transferring the semiconductor wafer W to the treatment chamber 6 of the heat treatment part 160. In this regard, similar to the first cooling chamber 131, when the semiconductor wafer W is transported into the second cooling chamber 141, a large amount of the air atmosphere is mixed in the second cooling chamber 141, and the oxygen concentration in the second cooling chamber 141 rises up to approximately several percent. Therefore, opening the gate valve 184 as is causes rises in oxygen concentrations in the transport chamber 170 and, in addition, the treatment chamber 6. Therefore, for a predetermined time period after the semiconductor wafer W is transported into the second cooling chamber 141 and the gate valve 182 is closed, the nitrogen gas is supplied at the large supply flow rate into the second cooling chamber 141 that is the enclosed space, and the atmosphere is exhausted at the large exhaust flow rate from the second cooling chamber 141. Consequently, the oxygen mixed in the second cooling chamber 141 as the semiconductor wafer W is transported in is quickly exhausted from the second cooling chamber 141, and the inside of the second cooling chamber 141 is replaced with a nitrogen atmosphere. As a result, the oxygen concentration having risen up to approximately several percent in the second cooling chamber 141 quickly lowers to 10 ppm or less. To prevent the air atmosphere from being mixed in as the semiconductor wafer W is transported in, the nitrogen gas may start being supplied at the large supply flow rate into the second cooling chamber 141 and the atmosphere may start being exhausted at the large exhaust flow rate from the second cooling chamber 141 a little before the semiconductor wafer W is transported into the second cooling chamber 141.

At a point in time when the predetermined time period passes after the semiconductor wafer W is transported into the second cooling chamber 141, a nitrogen gas supply flow rate for the second cooling chamber 141 is switched to the small supply flow rate, and an exhaust flow rate from the second cooling chamber 141 is switched to the small exhaust flow rate. Subsequently, the gate valve 184 opens between the second cooling chamber 141 and the transport chamber 170, and the transport robot 150 transports the semiconductor wafer W out of the second cooling chamber 141 to the transport chamber 170. The transport chamber 170 continues to be supplied with the nitrogen gas at all times, and has the nitrogen atmosphere inside. The transport robot 150 having taken out the semiconductor wafer W turns to face toward the heat treatment part 160. After the semiconductor wafer W is transported out, the gate valve 184 closes between the second cooling chamber 141 and the transport chamber 170.

Subsequently, the gate valve 185 opens between the treatment chamber 6 and the transport chamber 170, and the transport robot 150 transports the semiconductor wafer W into the treatment chamber 6. After the semiconductor wafer W is transported in, the gate valve 185 closes between the treatment chamber 6 and the transport chamber 170. The semiconductor wafer W transported into the treatment chamber 6 is preheated by the halogen lamps HL according to the above procedure, and then is subjected to the flash heating treatment by flash irradiation from the flash lamps FL.

After the flash heating treatment is finished, the gate valve 185 opens, and the transport robot 150 transports the semiconductor wafer W subjected to the flash heating treatment out of the treatment chamber 6 to the transport chamber 170. The transport robot 150 having taken out the semiconductor wafer W turns to face toward the second cooling chamber 141 of the cooler 140 from the treatment chamber 6. The gate valve 185 closes between the treatment chamber 6 and the transport chamber 170, and the gate valve 184 opens between the second cooling chamber 141 and the transport chamber 170. Subsequently, the transport robot 150 transports the semiconductor wafer W immediately after the flash heating, into the second cooling chamber 141. At this time, if a new untreated semiconductor wafer W is in the second cooling chamber 141, the untreated semiconductor wafer W is taken out and the treated semiconductor wafer W is transported into the second cooling chamber 141, whereby the wafers are replaced.

After the semiconductor wafer W subjected to the flash heating is transported into the second cooling chamber 141, the gate valve 184 closes between the second cooling chamber 141 and the transport chamber 170. The second cooling chamber 141 performs a cooling treatment on the semiconductor wafer W subjected to the flash heating treatment. For a predetermined time period after the semiconductor wafer W subjected to the heating treatment is transported into the second cooling chamber 141 and the gate valve 184 is closed, the nitrogen gas is supplied at the small supply flow rate into the second cooling chamber 141 that is the enclosed space, and the atmosphere is exhausted at the small exhaust flow rate from the second cooling chamber 141. At a point in time when the predetermined time period passes, the nitrogen gas supply flow rate for the second cooling chamber 141 is switched to the large supply flow rate, and the exhaust flow rate from the second cooling chamber 141 is switched to the large exhaust flow rate.

After the cooling treatment of the semiconductor wafer W is finished, the gate valve 182 opens between the second cooling chamber 141 and the indexer 101, and the transfer robot 120 transports the cooled semiconductor wafer W out of the second cooling chamber 141 to the indexer 101 to return the semiconductor wafer W to the carrier C. Subsequently, a new untreated semiconductor wafer W is transported from the indexer 101 into the second cooling chamber 141.

As described above, there is no difference in process content between the two transport paths of the “high throughput mode”, which are different only in that which one of the first cooling chamber 131 and the second cooling chamber 141 is used. In other words, the first cooling chamber 131 and the second cooling chamber 141 are parallel treatment parts and, in the “high throughput mode”, the two transport paths for performing a treatment of the same contents are available. In the first half of the transport path from the indexer 101 to the treatment chamber 6, the semiconductor wafer W having passed through the first cooling chamber 131 always passes through the first cooling chamber 131 in a second half of the transport path from the treatment chamber 6 to the indexer 101. Similarly, the semiconductor wafer W having passed through the second cooling chamber 141 in the first half of the transport path always passes through the second cooling chamber 141 in the second half of the transport path.

Which one of the transport path in the upper tier and the transport path in the lower tier in FIG. 11 is to be used for transporting the semiconductor wafer W to be treated is determined as appropriate. For example, a plurality of semiconductor wafers W constituting a lot may be alternately transported in the transport path in the upper tier and the transport path in the lower tier in FIG. 11. Specifically, odd-numbered wafers of a plurality of semiconductor wafers W constituting the lot may be transported in the transport path in the upper tier in FIG. 11, and the even-numbered wafers may be transported in the transport path in the lower tier.

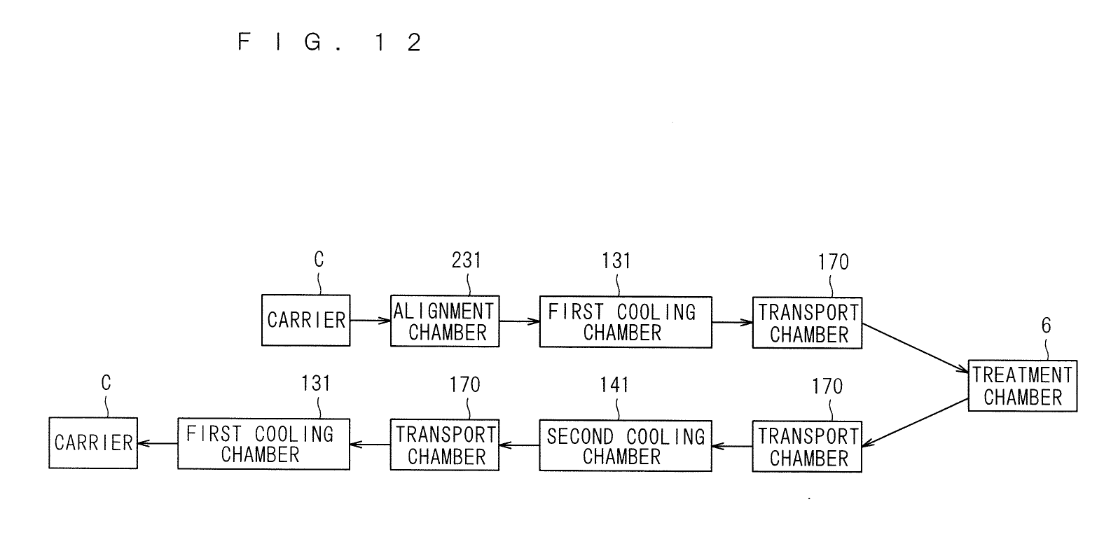

FIG. 12 is a view showing a transport path of the semiconductor wafer W according to the “low oxygen concentration mode”. First, a plurality of untreated semiconductor wafers W received in the carriers C is placed on the load port 110 of the indexer 101. The transfer robot 120 takes out the semiconductor wafers W one by one from the carrier C to transport the semiconductor wafers W into the alignment chamber 231 of the alignment part 230. Next, the transfer robot 120 takes out the semiconductor wafer W whose direction has been adjusted, from the alignment chamber 231 to transport this semiconductor wafer W from the indexer 101 into the first cooling chamber 131 of the cooler 130. At a point in time when the semiconductor wafer W is transported into the first cooling chamber 131, the gate valve 181 closes between the first cooling chamber 131 and the indexer 101. The gate valve 183 closes between the first cooling chamber 131 and the transport chamber 170, too. Therefore, the inside of the first cooling chamber 131 is the enclosed space.

The first cooling chamber 131, which is originally for cooling the semiconductor wafer W, also functions as the path for transferring the semiconductor wafer W between the transfer robot 120 and the transport robot 150 in the low oxygen concentration mode. In this regard, as described above, since the indexer 101 is exposed to the air atmosphere, when the semiconductor wafer W is transported into the first cooling chamber 131, a large amount of the air atmosphere is mixed in the first cooling chamber 131, and the oxygen concentration in the first cooling chamber 131 rises to approximately several percent. Therefore, opening the gate valve 183 as is causes rises in oxygen concentrations in the transport chamber 170 and, in addition, the treatment chamber 6. Therefore, for a predetermined time period after the semiconductor wafer W is transported into the first cooling chamber 131 and the gate valve 181 is closed, nitrogen gas is supplied at the large supply flow rate into the first cooling chamber 131 that is the enclosed space, and the atmosphere is exhausted at the large exhaust flow rate from the first cooling chamber 131. Consequently, the oxygen mixed in the first cooling chamber 131 as the semiconductor wafer W is transported in is quickly exhausted from the first cooling chamber 131, and the inside of the first cooling chamber 131 is replaced with a nitrogen atmosphere. As a result, the oxygen concentration having risen up to approximately several percent in the first cooling chamber 131 quickly lowers to 10 ppm or less. To reduce the air atmosphere mixed in as the semiconductor wafer W is transported in, the nitrogen gas may start being supplied at the large supply flow rate into the first cooling chamber 131 and the atmosphere may start being exhausted at the large exhaust flow rate from the first cooling chamber 131 a little before the semiconductor wafer W is transported into the first cooling chamber 131.

At a point in time when the predetermined time period passes after the semiconductor wafer W is transported into the first cooling chamber 131, a nitrogen gas supply flow rate for the first cooling chamber 131 is switched to the small supply flow rate, and an exhaust flow rate from the first cooling chamber 131 is switched to the small exhaust flow rate. Subsequently, the gate valve 183 opens between the first cooling chamber 131 and the transport chamber 170, and the transport robot 150 transports the semiconductor wafer W out of the first cooling chamber 131. The transport chamber 170 continues to be supplied with the nitrogen gas at all times, and has the nitrogen atmosphere inside. The transport robot 150 having taken out the semiconductor wafer W turns to face toward the heat treatment part 160. After the semiconductor wafer W is transported out, the gate valve 183 closes between the first cooling chamber 131 and the transport chamber 170.

Subsequently, the gate valve 185 opens between the treatment chamber 6 and the transport chamber 170, and the transport robot 150 transports the semiconductor wafer W into the treatment chamber 6. After the semiconductor wafer W is transported in, the gate valve 185 closes between the treatment chamber 6 and the transport chamber 170. The semiconductor wafer W transported into the treatment chamber 6 is preheated by the halogen lamps HL according to the above procedure, and then is subjected to the flash heating treatment by flash irradiation from the flash lamps FL.

After the flash heating treatment is finished, the gate valve 185 opens, and the transport robot 150 transports the semiconductor wafer W subjected to the flash heating treatment out of the treatment chamber 6. The transport robot 150 having taken out the semiconductor wafer W turns to face toward the second cooling chamber 141 of the cooler 140 from the treatment chamber 6. The gate valve 185 closes between the treatment chamber 6 and the transport chamber 170, and the gate valve 184 opens between the second cooling chamber 141 and the transport chamber 170. Subsequently, the transport robot 150 transports the semiconductor wafer W immediately after the flash heating, into the second cooling chamber 141. At this time, if the semiconductor wafer W subjected to the cooling treatment is in the second cooling chamber 141, the semiconductor wafer W subjected to the cooling treatment is taken out and the semiconductor wafer W subjected to the heating treatment is transported into the second cooling chamber 141, whereby the wafers are replaced.

After the semiconductor wafer W subjected to the flash heating is transported into the second cooling chamber 141, the gate valve 184 closes between the second cooling chamber 141 and the transport chamber 170. The second cooling chamber 141 performs a cooling treatment on the semiconductor wafer W subjected to the flash heating treatment. The nitrogen gas continues to be supplied at the small supply flow rate into the second cooling chamber 141, and the atmosphere is exhausted at the small exhaust flow rate from the second cooling chamber 141.

After the cooling treatment of the semiconductor wafer W is finished, the gate valve 184 opens between the second cooling chamber 141 and the transport chamber 170 again, and the transport robot 150 transports the semiconductor wafer W subjected to the cooling treatment out of the second cooling chamber 141 to the transport chamber 170. The transport robot 150 having taken out the semiconductor wafer W turns to face toward the first cooling chamber 131 from the second cooling chamber 141. The gate valve 184 closes between the second cooling chamber 141 and the transport chamber 170, and the gate valve 183 opens between the first cooling chamber 131 and the transport chamber 170. Subsequently, the transport robot 150 transports the semiconductor wafer W subjected to the cooling treatment into the first cooling chamber 131. At this time, if a new untreated semiconductor wafer W is in the first cooling chamber 131, the transport robot 150 takes out the untreated semiconductor wafer W and transports the semiconductor wafer W subjected to the cooling treatment into the first cooling chamber 131, whereby the wafers are replaced.

After the semiconductor wafer W subjected to the cooling treatment is transported into the first cooling chamber 131 and the gate valve 183 is closed, the nitrogen gas supply flow rate for the first cooling chamber 131 is switched to the large supply flow rate, and the exhaust flow rate from the first cooling chamber 131 is switched to the large exhaust flow rate. Subsequently, the gate valve 181 opens between the first cooling chamber 131 and the indexer 101, and the transfer robot 120 transports the cooled semiconductor wafer W out of the first cooling chamber 131 to the indexer 101 to return the semiconductor wafer W to the carrier C. Subsequently, a new untreated semiconductor wafer W is transported from the indexer 101 into the first cooling chamber 131.

As described above, in the “low oxygen concentration mode”, the first cooling chamber 131 is used only as the path for transferring the semiconductor wafer W between the transfer robot 120 and the transport robot 150, and the second cooling chamber 141 is used only as a dedicated cooling unit for cooling the semiconductor wafer W subjected to the flash heating. According to the “low oxygen concentration mode”, the gate valve 182 is closed at all times, and the second cooling chamber 141 and the indexer 101 exposed to the air atmosphere are not in communication with each other. Therefore, the air atmosphere is not trapped, and the oxygen concentration in the second cooling chamber 141 does not rapidly rise. Consequently, it is possible to maintain a low oxygen concentration in the second cooling chamber 141 at all times compared to the “high throughput mode”. According to the “low oxygen concentration mode”, the oxygen concentration in the second cooling chamber 141 is maintained at 1 ppm or less. Consequently, when a cooling treatment of the semiconductor wafer W subjected to flash heating needs to be performed at a lower oxygen concentration, the “low oxygen concentration mode” is suitable. In this regard, according to the “low oxygen concentration mode”, the path for transferring the semiconductor wafer W between the transfer robot 120 of the indexer 101 and the transport robot 150 is only the first cooling chamber 131, and a transport throughput is lower than that of the “high throughput mode”.

According to the “low oxygen concentration mode”, by supplying the nitrogen gas at the large supply flow rate and exhausting the atmosphere at the large exhaust flow rate for a predetermined time period after the semiconductor wafer W is transported into the first cooling chamber 131, it is possible to quickly exhaust the oxygen mixed in the first cooling chamber 131 as the semiconductor wafer W is transported in. Consequently, it is possible to suppress a rise in the oxygen concentration in the transport chamber 170, and more effectively maintain a low oxygen concentration in the second cooling chamber 141.

On the other hand, in the “high throughput mode”, both of the first cooling chamber 131 and the second cooling chamber 141 are used as paths for transporting the semiconductor wafer W between the transfer robot 120 and the transport robot 150. Both of the first cooling chamber 131 and the second cooling chamber 141 are used as cooling units, too, for cooling the semiconductor wafer W subjected to flash heating. For the “high throughput mode”, the two paths for transferring the semiconductor wafer W between the transfer robot 120 and the transport robot 150 are provided, and consequently a transport throughput of the semiconductor wafer W can be increased compared to the “low oxygen concentration mode”. Consequently, when the semiconductor wafer W needs to be treated in the high throughput mode, the “high throughput mode” is suitable.

In this regard, in the “high throughput mode”, both of the first cooling chamber 131 and the second cooling chamber 141 are used as the paths, and therefore the air atmosphere is mixed in both of the first cooling chamber 131 and the second cooling chamber 141 as the untreated semiconductor wafer W is transported in. By supplying the nitrogen gas at the large supply flow rate, and exhausting the atmosphere at the large exhaust flow rate for a predetermined time period after the semiconductor wafer W is transported into the first cooling chamber 131 and the second cooling chamber 141, it is possible to quickly exhaust the oxygen mixed in the chambers. However, the oxygen concentrations of the first cooling chamber 131 and the second cooling chamber 141 in the “high throughput mode” are higher than the oxygen concentration of the second cooling chamber 141 that is the dedicated cooling unit in the “low oxygen concentration mode”. The oxygen concentrations of the first cooling chamber 131 and the second cooling chamber 141 in the “high throughput mode” are several ppm to 10 ppm.

According to the first preferred embodiment, the two transport modes of the “high throughput mode” and the “low oxygen concentration mode” can be switched as appropriate. When a high throughput is requested, the “high throughput mode” is set, and when a cooling treatment at a lower oxygen concentration is requested, the “low oxygen concentration mode” is set. Specifically, the two transport modes may be set by setting flags each according to, for example, a recipe that describes various treatment conditions of the semiconductor wafer W. The controller 3 having been switched to the set transport mode controls the transfer robot 120 and the transport robot 150 according to this transport mode to transport the semiconductor wafer W.

### Second Preferred Embodiment

Next, a second preferred embodiment according to the present invention will be described. The heat treatment apparatus 100 according to the second preferred embodiment is similar in overall configuration to that according to the first preferred embodiment. A procedure for the treatment of the semiconductor wafer W in the heat treatment apparatus 100 according to the second preferred embodiment is also similar to that according to the first preferred embodiment. According to the first preferred embodiment, the two transport modes of the “high throughput mode” and the “low oxygen concentration mode” can be switched as appropriate. However, according to the second preferred embodiment, the two transport modes are automatically switched.

According to the second preferred embodiment, the transport mode is switched to the “high throughput mode” or the “low oxygen concentration mode” based on a stay time of the semiconductor wafer W in the treatment chamber 6 of the heat treatment part 160. The stay time of the semiconductor wafer W in the treatment chamber 6 is found out from the recipe that describes the various treatment conditions. The controller 3 selects the “low oxygen concentration mode” when the stay time of the semiconductor wafer W in the treatment chamber 6 described in the recipe is equal to or more than a predetermined threshold (e.g., 80 seconds or more). The controller 3 selects the “high throughput mode” when the stay time of the semiconductor wafer W in the treatment chamber 6 described in the recipe is less than the predetermined threshold.

When the stay time of the semiconductor wafer W in the treatment chamber 6 described in the recipe is long, the throughput of the heat treatment apparatus 100 is also naturally low. Irrespectively of a throughput and from a viewpoint of process performance, it is preferable to perform a cooling treatment on the semiconductor wafer W at a lower oxygen concentration after flash heating. Consequently, when the stay time of the semiconductor wafer W in the treatment chamber 6 described in the recipe is equal to or more than the predetermined threshold and is relatively long, it is possible to perform the cooling treatment on the semiconductor wafer W at a lower oxygen concentration after the flash heating by setting the transport mode to the “low oxygen concentration mode”.

On the other hand, when the stay time of the semiconductor wafer W in the treatment chamber 6 described in the recipe is short, a high throughput is requested. When the throughput is increased while the transport mode is the “low oxygen concentration mode”, a nitrogen purge time for the first cooling chamber 131 used as the path with the untreated semiconductor wafer W transported thereinto cannot be sufficiently secured. As a result, the oxygen concentration in the transport chamber 170 rises. When the oxygen concentration in the transport chamber 170 rises, the oxygen concentration in the second cooling chamber 141 used as the dedicated cooling unit also rises. When the throughput is increased to a certain throughput or more in the “low oxygen concentration mode”, the oxygen concentration in the second cooling chamber 141 becomes substantially the same as that in the “high throughput mode”. In this case, there is no significance of the “low oxygen concentration mode” of a relatively low throughput. Consequently, when the stay time of the semiconductor wafer W in the treatment chamber 6 described in the recipe is less than the predetermined threshold and is relatively short, the transport mode is set to the “high throughput mode. With this, it is possible to treat the semiconductor wafer W with a high throughput.

Thus, according to the second preferred embodiment, a more suitable transport mode is selected based on the stay time of the semiconductor wafer W in the treatment chamber 6 described in the recipe, and the semiconductor wafer W is transported according to this selected transport mode.

### Third Preferred Embodiment

Next, a third preferred embodiment according to the present invention will be described. The heat treatment apparatus 100 according to the third preferred embodiment is similar in overall configuration to that according to the first preferred embodiment. A procedure for the treatment of the semiconductor wafer W in the heat treatment apparatus 100 according to the third preferred embodiment is also similar to that according to the first preferred embodiment. According to the first preferred embodiment, the two transport modes of the “high throughput mode” and the “low oxygen concentration mode” can be switched as appropriate. However, according to the third preferred embodiment, the two transport modes are automatically switched.

According to the third preferred embodiment, the transport mode is switched to the “high throughput mode” or the “low oxygen concentration mode” based on the oxygen concentration in the transport chamber 170. The oxygen concentration in the transport chamber 170 is measured by the oximeter 155. The controller 3 selects the “high throughput mode” when the oxygen concentration in the transport chamber 170 measured by the oximeter 155 is equal to or more than a predetermined threshold (e.g., 1.5 ppm or more). The controller 3 selects the “low oxygen concentration mode” when the oxygen concentration in the transport chamber 170 is less than the predetermined threshold.

As described above, irrespectively of a throughput and from a viewpoint of process performance, it is preferable to perform a cooling treatment on the semiconductor wafer W at a lower oxygen concentration after flash heating, and the “low oxygen concentration mode” is suitable. However, even in the “low oxygen concentration mode”, an increase in the throughput raises the oxygen concentration in the transport chamber 170, and makes it difficult to maintain the low oxygen concentration in the second cooling chamber 141 used as the dedicated cooling unit. When the throughput is increased to a certain throughput or more in the “low oxygen concentration mode”, the oxygen concentration in the second cooling chamber 141 becomes substantially the same as that in the “high throughput mode”. In this case, there is no significance of the “low oxygen concentration mode” of a relatively low throughput.

Therefore, according to the third preferred embodiment, when the oxygen concentration in the transport chamber 170 measured by the oximeter 155 is less than the predetermined threshold, the “low oxygen concentration mode” is selected so that a cooling treatment on the semiconductor wafer W is performed at a lower oxygen concentration after flash heating. On the other hand, when the oxygen concentration in the transport chamber 170 is equal to or more than the predetermined threshold, there is no significance of the “low oxygen concentration mode”. Therefore, the transport mode is set to the “high throughput mode” to treat the semiconductor wafer W with a high throughput. The threshold of this oxygen concentration may be set to the oxygen concentration in the transport chamber 170 in a case where the throughput is increased in the “low oxygen concentration mode” and the oxygen concentration in the second cooling chamber 141 becomes substantially the same as that of the “high throughput mode”.

Thus, according to the third preferred embodiment, a more suitable transport mode is selected based on the oxygen concentration in the transport chamber 170 measured by the oximeter 155, and the semiconductor wafer W is transported according to this selected transport mode. It is not preferable that a transport mode is switched within a lot (a group of semiconductor wafers W to be treated under the same condition and same treatment contents). Therefore, it is suitable for the oximeter 155 to measure the oxygen concentration on a lot-by-lot basis.

### Fourth Preferred Embodiment

Next, a fourth preferred embodiment according to the present invention will be described. The heat treatment apparatus 100 according to the fourth preferred embodiment is similar in overall configuration to that according to the first preferred embodiment. A procedure for the treatment of the semiconductor wafer W in the heat treatment apparatus 100 according to the fourth preferred embodiment is also similar to that according to the first preferred embodiment. According to the fourth preferred embodiment, the “high throughput mode” and the “low oxygen concentration mode” and, in addition, a “contamination inspection mode” can be selected.

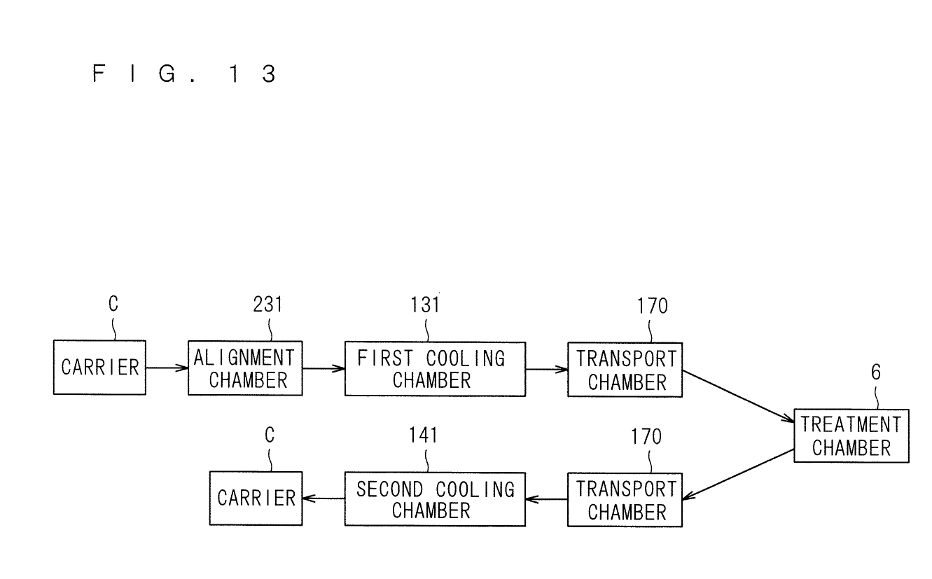

FIG. 13 is a view showing a transport path of the semiconductor wafer W according to the “contamination inspection mode”. First, a plurality of untreated semiconductor wafers W received in the carriers C is placed on the load port 110 of the indexer 101. The transfer robot 120 takes out the semiconductor wafer W from the carrier C to transport the semiconductor wafer W into the alignment chamber 231 of the alignment part 230. Next, the transfer robot 120 takes out the semiconductor wafer W whose direction has been adjusted, from the alignment chamber 231 to transport this semiconductor wafer W from the indexer 101 into the first cooling chamber 131 of the cooler 130. The same nitrogen purge as the above is performed in the first cooling chamber 131 to replace the inside of the first cooling chamber 131 with a nitrogen atmosphere.

Next, the transport robot 150 transports the semiconductor wafer W out of the first cooling chamber 131 to the transport chamber 170 to transport the semiconductor wafer W into the treatment chamber 6 of the heat treatment part 160. The semiconductor wafer W transported into the treatment chamber 6 is preheated by the halogen lamps HL according to the above procedure, and then is subjected to the flash heating treatment by flash irradiation from the flash lamps FL.

After the flash heating treatment is finished, the transport robot 150 transports the semiconductor wafer W subjected to the flash heating out of the treatment chamber 6 to the transport chamber 170. Subsequently, the transport robot 150 transports the semiconductor wafer W immediately after the flash heating, into the second cooling chamber 141. The second cooling chamber 141 performs a cooling treatment on the semiconductor wafer W subjected to the flash heating treatment.

After the cooling treatment of the semiconductor wafer W is finished, the transfer robot 120 transports the cooled semiconductor wafer W out of the second cooling chamber 141 to the indexer 101 to return the semiconductor wafer W to the carrier C. As the semiconductor wafer W is transported, each gate valve is opened and closed in the same way as described in the first preferred embodiment.

The heat treatment apparatus 100 performs contamination inspection during maintenance, for example. The contamination inspection refers to inspection of metal contamination and particle adhesion on the semiconductor wafer W during a treatment in the heat treatment apparatus 100. During the contamination inspection, after the semiconductor wafer W to be inspected is transported in the heat treatment apparatus 100 and is subjected to a flash heating treatment, metal contamination inspection and particle adhesion inspection are performed on the treated semiconductor wafer W. In this case, if the semiconductor wafer W is transported in the above “high throughput mode” in which the two transport paths are available, two semiconductor wafers W are consumed for inspection, and thus the inspection is necessarily performed twice. In the “contamination inspection mode” in the fourth preferred embodiment, one transport path is available. Therefore, it is sufficient to consume one semiconductor wafer W for inspection and perform the metal contamination inspection and the particle adhesion inspection once. The “contamination inspection mode” is selected as appropriate during maintenance of the heat treatment apparatus 100, and the controller 3 having been switched to the “contamination inspection mode” controls the transfer robot 120 and the transport robot 150 according to the transport procedure shown in FIG. 13 to transport the semiconductor wafer W to be inspected. Although one transport path is available also in the “low oxygen concentration mode”, the semiconductor wafer W does not move between the second cooling chamber 141 and the indexer 101, and therefore it is not possible to detect contamination caused by the gate valve 182.

### Fifth Preferred Embodiment

Next, a fifth preferred embodiment according to the present invention will be described. The heat treatment apparatus 100 according to the fifth preferred embodiment is similar in overall configuration to that according to the first preferred embodiment. A procedure for the treatment of the semiconductor wafer W in the heat treatment apparatus 100 according to the fifth preferred embodiment is also similar to that according to the first preferred embodiment. In the fifth preferred embodiment, a “reflectance measurement mode” can be further selected.

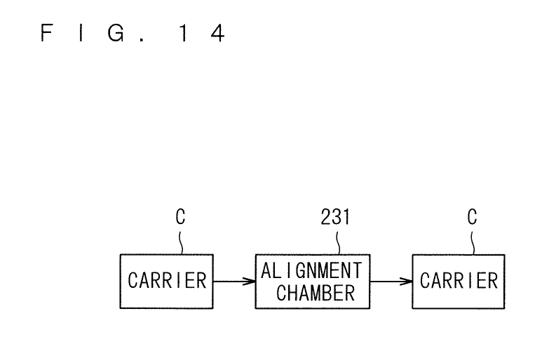

FIG. 14 is a view showing a transport path of the semiconductor wafer W according to the “reflectance measurement mode”. Similar to the above, a plurality of untreated semiconductor wafers W received in the carriers C is placed on the load port 110 of the indexer 101. The transfer robot 120 takes out the semiconductor wafer W from the carrier C to transport the semiconductor wafer W into the alignment chamber 231 of the alignment part 230. In the alignment chamber 231, the reflectance measurement part 232 measures a reflectance of a front surface of the semiconductor wafer W. After the reflectance of the front surface is measured, the transfer robot 120 takes out the semiconductor wafer W from the alignment chamber 231 to the indexer 101, and returns this semiconductor wafer W to the carrier C again.

Thus, according to the “reflectance measurement mode”, the semiconductor wafer W is transported from the indexer 101 into the alignment chamber 231 without being transported into the treatment chamber 6, and after the reflectance of a wafer surface is measured, the semiconductor wafer W is returned from the alignment chamber 231 to the indexer 101. The semiconductor wafer W is not transported into the treatment chamber 6 having a high temperature, so that it is possible to measure the reflectance without a heat influence on the semiconductor wafer W. The “reflectance measurement mode” is selected as appropriate as need arises, and the controller 3 having been switched to the “reflectance measurement mode” controls the transfer robot 120 and the transport robot 150 according to the transport procedure shown in FIG. 14 to transport the semiconductor wafer W.

### Modifications

While the preferred embodiments according to the present invention have been described hereinabove, various modifications of the present invention are possible in addition to those described above without departing from the scope and spirit of the present invention. For example, the first cooling chamber 131 as the path for transferring the semiconductor wafer W and the second cooling chamber 141 as the dedicated cooling unit in the “low oxygen concentration mode” according to the first preferred embodiment may be operated in a reverse way. In other words, the first cooling chamber 131 may be used only as a dedicated cooling unit for cooling the semiconductor wafer W subjected to flash heating, and the second cooling chamber 141 may be used only as a path for transferring the semiconductor wafer W between the transfer robot 120 and the transport robot 150. Which one of the first cooling chamber 131 and the second cooling chamber 141 is to be used as a path (or as a cooling unit) is determined as appropriate. For example, a cooling chamber into which the first semiconductor wafer W of a lot to be transported in the “low oxygen concentration mode” is transported may be used as a path, and the remainder one may be used as a dedicated cooling unit.

In the aforementioned preferred embodiments, the halogen lamps HL irradiate the semiconductor wafer W with light for preheating. However, instead, a susceptor for holding the semiconductor wafer W may be placed on a hot plate to preheat the semiconductor wafer W by heat conduction from the hot plate.

Although the 30 flash lamps FL are provided in the flash lamp house 5 in each of the aforementioned preferred embodiments, the present invention is not limited to this. Any number of flash lamps FL may be provided. The flash lamps FL are not limited to the xenon flash lamps, but may be krypton flash lamps. Also, the number of halogen lamps HL provided in the halogen lamp house 4 is not limited to 40. Any number of halogen lamps HL may be provided.

In the aforementioned preferred embodiments, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) may be used as continuous lighting lamps to preheat the semiconductor wafer W.

Moreover, a substrate to be treated by the heat treatment apparatus 100 is not limited to a semiconductor wafer, but may be a glass substrate for use in a flat panel display for a liquid crystal display apparatus and the like, and a substrate for a solar cell. Also, the technique according to the present invention may be applied to the heat treatment of high dielectric constant gate insulator films (high-k films), to the joining of metal and silicon, and to the crystallization of polysilicon.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus for heating a substrate by irradiating the substrate with a flash of light, the heat treatment apparatus comprising:
an indexer including a transfer robot, and for transporting an untreated substrate into the heat treatment apparatus and transporting a treated substrate out of the heat treatment apparatus;
a transport chamber including a transport robot;
a first cooling chamber connected to said transport chamber and said indexer;
a second cooling chamber connected to said transport chamber and said indexer;
a treatment chamber connected to said transport chamber;
a flash lamp for heating the substrate by irradiating the substrate received in said treatment chamber, with a flash of light; and
a controller for controlling said transfer robot and said transport robot,
wherein said controller controls said transfer robot and said transport robot with said controller switched to one of
a high throughput mode of transporting an untreated first substrate from said indexer into said first cooling chamber, supplying nitrogen gas into said first cooling chamber, replacing an inside of the first cooling chamber with a nitrogen atmosphere, then transporting the first substrate from said first cooling chamber into said treatment chamber via said transport chamber, transferring the first substrate subjected to a heating treatment from said treatment chamber to said first cooling chamber via said transport chamber, cooling the first substrate, then transporting the first substrate out to said indexer, transporting an untreated second substrate from said indexer into said second cooling chamber, supplying the nitrogen gas into said second cooling chamber, replacing an inside of the second cooling chamber with the nitrogen atmosphere, then transporting the second substrate from said second cooling chamber into said treatment chamber via said transport chamber, transferring the second substrate subjected to the heating treatment from said treatment chamber to said second cooling chamber via said transport chamber, cooling the second substrate, and then transporting the second substrate out to said indexer, and
a low oxygen concentration mode of transporting an untreated substrate from said indexer into said first cooling chamber, supplying the nitrogen gas into said first cooling chamber, replacing the inside of the first cooling chamber with the nitrogen atmosphere, then transporting said substrate from said first cooling chamber into said treatment chamber via said transport chamber, transferring said substrate subjected to the heating treatment from said treatment chamber to said second cooling chamber via said transport chamber, cooling said substrate, and then transporting the substrate out to said indexer via said transport chamber and said first cooling chamber.

2. The heat treatment apparatus according to claim 1, wherein said controller is configured to select said low oxygen concentration mode when a stay time of the substrate in said treatment chamber is equal to or more than a predetermined threshold, and select said high throughput mode when the stay time is less than said threshold.

3. The heat treatment apparatus according to claim 1, further comprising an oxygen concentration measurement part for measuring an oxygen concentration in said transport chamber,
wherein said controller is configured to select said high throughput mode when the oxygen concentration in said transport chamber is equal to or more than a predetermined threshold, and select said low oxygen concentration mode when the oxygen concentration is less than said threshold.

4. The heat treatment apparatus according to claim 1, wherein said controller is configured to be further switchable to a contamination inspection mode of transporting the untreated substrate from said indexer into said first cooling chamber, supplying the nitrogen gas into said first cooling chamber, replacing the inside of the first cooling chamber with the nitrogen atmosphere, then transporting said substrate from said first cooling chamber into said treatment chamber via said transport chamber, transferring said substrate subjected to the heating treatment from said treatment chamber to said second cooling chamber via said transport chamber, cooling said substrate, and then transporting said substrate out to said indexer.

5. The heat treatment apparatus according to claim 1, further comprising an alignment chamber connected to said indexer, and including a reflectance measurement part for measuring a reflectance of the substrate,
wherein said controller is further switchable to a reflectance measurement mode of transporting the untreated substrate from said indexer into said alignment chamber, measuring the reflectance of said substrate, and then returning said substrate from said alignment chamber to said indexer.

6. A heat treatment method for heating a substrate by irradiating the substrate with a flash of light,
wherein the substrate is transported while one of two modes is selected, the modes including
a high throughput mode of transporting an untreated first substrate from an indexer into a first cooling chamber, supplying nitrogen gas into said first cooling chamber, replacing an inside of the first cooling chamber with a nitrogen atmosphere, then transporting the first substrate from said first cooling chamber into a treatment chamber via a transport chamber, heating the first substrate in said treatment chamber by irradiating the first substrate with the flash of light, then transferring the first substrate from said treatment chamber to said first cooling chamber via said transport chamber, cooling the first substrate, then transporting the first substrate out to said indexer, transporting an untreated second substrate from the indexer into a second cooling chamber, supplying the nitrogen gas into said second cooling chamber, replacing an inside of the second cooling chamber with the nitrogen atmosphere, then transporting the second substrate from said second cooling chamber into said treatment chamber via said transport chamber, heating the second substrate in said treatment chamber by irradiating the second substrate with the flash of light, then transferring the second substrate from said treatment chamber to said second cooling chamber via said transport chamber, cooling the second substrate, and then transporting the second substrate out to said indexer, and
a low oxygen concentration mode of transporting an untreated substrate from said indexer into said first cooling chamber, supplying the nitrogen gas into said first cooling chamber, replacing the inside of the first cooling chamber with the nitrogen atmosphere, then transporting said substrate from said first cooling chamber into said treatment chamber via said transport chamber, heating said substrate in said treatment chamber by irradiating said substrate with the flash of light, then transferring said substrate from said treatment chamber to said second cooling chamber via said transport chamber, cooling said substrate, and then transporting said substrate out to said indexer via said transport chamber and said first cooling chamber.

7. The heat treatment method according to claim 6, wherein said low oxygen concentration mode is selected when a stay time of the substrate in said treatment chamber is equal to or more than a predetermined threshold, and said high throughput mode is selected when the stay time is less than said threshold.

8. The heat treatment method according to claim 6, wherein said high throughput mode is selected when an oxygen concentration in said transport chamber is equal to or more than a predetermined threshold, and said low oxygen concentration mode is selected when the oxygen concentration is less than said threshold.

9. The heat treatment method according to claim 6, wherein the heat treatment method is further switchable to a contamination inspection mode of transporting the untreated substrate from said indexer into said first cooling chamber, supplying the nitrogen gas into said first cooling chamber, replacing the inside of the first cooling chamber with the nitrogen atmosphere, then transporting said substrate from said first cooling chamber into said treatment chamber via said transport chamber, heating said substrate in said treatment chamber by irradiating said substrate with the flash of light, then transferring said substrate from said treatment chamber to said second cooling chamber via said transport chamber, cooling said substrate, and then transporting said substrate out to said indexer.

10. The heat treatment method according to claim 6, wherein the heat treatment method is further switchable to a reflectance measurement mode of transporting the untreated substrate from said indexer into an alignment chamber connected to said indexer, measuring the reflectance of said substrate, and then returning said substrate from said alignment chamber to said indexer.
